(19) United States
(12) Patent Application Publication
(10) Pub. No.: US 2026/0351182 A1
(43) Pub. Date: Nov. 5, 2026

(54) DISPLAY MODULE AND DISPLAY DEVICE

(71) Applicant: Xiamen Tianma Display Technology Co., Ltd., Xiamen (CN)

(72) Inventors: Xuehuan FENG, Xiamen (CN); Huijun JIN, Xiamen (CN); Zongcai DING, Xiamen (CN)

(73) Assignee: Xiamen Tianma Display Technology Co., Ltd., Xiamen (CN)

(21) Appl. No.: 19/723,491

(22) Filed: Jun. 29, 2026

(30) Foreign Application Priority Data
Dec. 31, 2025 (CN) 202512058855.0

(51) Int. Cl. G09G 3/3233

(52) U.S. Cl. CPC G09G 3/3233; G09G 2300/0426; G09G 2310/0286; G09G 2320/0233; G09G 2330/021

(57) ABSTRACT

Provided are a display panel and a display device. The display panel includes pixel driving circuits, a first pixel driving circuit, a second pixel driving circuit, a first data line, a first scan line, and a second scan line. The first data line extends along a second direction and is configured to provide a data signal to the first pixel driving circuit and the second pixel driving circuit. The first scan line and the second scan line respectively provide scan signals to gates of first transistors of the corresponding one of the first pixel driving circuit or the second pixel driving circuit. The distance from the first transistor to a corresponding drive transistor in the first pixel driving circuit is D1, and the distance from the first transistor to a corresponding drive transistor in the second pixel driving circuit is D2. |D1−D2|>0.

### CROSS-REFERENCE TO RELATED APPLICATION

This application claims priority to Chinese patent application No. 202512058855.0 filed with the China National Intellectual Property Administration (CNIPA) on Dec. 31, 2025, the disclosure of which is incorporated herein by reference in its entirety.

### TECHNICAL FIELD

The present disclosure relates to the field of display technology, and in particular, to a display panel and a display device.

### BACKGROUND

Pixels in an organic light-emitting display (OLED) device include organic light-emitting diodes (OLEDs) that emit light by themselves to display images through OLED light emission.

An OLED display panel includes sub-pixels arranged in an array. The sub-pixels include multiple sub-pixel columns arranged sequentially along the row direction. In the related art, each column of sub-pixels requires a separate data line to provide data signals. However, an excessive number of data lines results in an excessive number of driver chips, leading to excessively high costs.

### SUMMARY

Embodiments of the present disclosure provide a display panel and a display device.

An embodiment of the present disclosure provides a display panel. The display panel includes a substrate, pixel driving circuits, a first data line, a first scan line, and a second scan line.

A pixel driving circuit at least includes a first transistor and a drive transistor. A gate of the first transistor is configured to receive a scan signal. The pixel driving circuits at least include a first pixel driving circuit and a second pixel driving circuit arranged along a first direction.

The first data line extends along a second direction and is configured to provide a data signal to the first pixel driving circuit and the second pixel driving circuit. The first direction intersects with the second direction.

The first scan line and a second scan line extend along the first direction. The first scan line is configured to provide the scan signal to a gate of a first transistor of one of the first pixel driving circuit or the second pixel driving circuit. The second scan line is configured to provide the scan signal to a gate of a first transistor of the other of the first pixel driving circuit or the second pixel driving circuit.

Along the second direction, the distance from the first transistor of the first pixel driving circuit to a corresponding drive transistor of the first pixel driving circuit is D1, the distance from the first transistor of the second pixel driving circuit to a corresponding drive transistor of the second pixel driving circuit is D2, and |D1−D2|>0.

In one or more embodiments, the pixel driving circuits also include a third pixel driving circuit and a fourth pixel driving circuit arranged along the first direction. Along the first direction, the first pixel driving circuit, the second pixel driving circuit, the third pixel driving circuit, and the fourth pixel driving circuit constitute a pixel unit. The display panel also includes a second data line extending along the second direction. The second data line is configured to provide a data signal to the third pixel driving circuit and the fourth pixel driving circuit. Along the second direction, the distance from the first transistor of the third pixel driving circuit to a corresponding drive transistor of the third pixel driving circuit is D3, the distance from the first transistor of the fourth pixel driving circuit to a corresponding drive transistor of the fourth pixel driving circuit is D4, and |D3−D4|>0.

In one or more embodiments, the first scan line is configured to provide the scan signal to a gate of a first transistor of one of the third pixel driving circuit or the fourth pixel driving circuit, and the second scan line is configured to provide the scan signal to a gate of a first transistor of the other of the third pixel driving circuit or the fourth pixel driving circuit.

In one or more embodiments, the first scan line is configured to provide the scan signal to the gate of the first transistor of the first pixel driving circuit and the gate of the first transistor of the third pixel driving circuit, the second scan line is configured to provide the scan signal to the gate of the first transistor of the second pixel driving circuit and the gate of the first transistor of the fourth pixel driving circuit, D1=D3, and D2=D4.

In one or more embodiments, in a direction perpendicular to a plane where the substrate is located, the projection of the first scan line at least partially overlaps with the gate of the first transistor of the first pixel driving circuit, and the projection of the second scan line at least partially overlaps with the gate of the first transistor of the second pixel driving circuit. In the direction perpendicular to the plane where the substrate is located, the projection of the first scan line at least partially overlaps with the gate of the first transistor of the third pixel driving circuit, and the projection of the second scan line at least partially overlaps with the gate of the first transistor of the fourth pixel driving circuit.

In one or more embodiments, the display panel also includes a shift register circuit. Multiple pixel units are arranged along the first direction to form a pixel driving circuit row, and the shift register circuit is electrically connected to the pixel driving circuit row correspondingly and configured to output the scan signal. In one pixel driving circuit row, the first scan line is configured to provide the scan signal to the gate of the first transistor of the first pixel driving circuit and the gate of the first transistor of the third pixel driving circuit, and the second scan line is configured to provide the scan signal to the gate of the first transistor of the second pixel driving circuit and the gate of the first transistor of the fourth pixel driving circuit.

In one or more embodiments, the display panel also includes a shift register circuit. Multiple pixel units are arranged along the first direction to form pixel driving circuit rows, and the shift register circuit is electrically connected to the pixel driving circuit rows correspondingly and configured to output the scan signal. In an i-th pixel driving circuit row, the first scan line is configured to provide the scan signal to the gate of the first transistor of the first pixel driving circuit and the gate of the first transistor of the third pixel driving circuit, and the second scan line is configured to provide the scan signal to the gate of the first transistor of the second pixel driving circuit and the gate of the first transistor of the fourth pixel driving circuit. In an (i+1)-th pixel driving circuit row, the first scan line is configured to provide the scan signal to the gate of the first transistor of the second pixel driving circuit and the gate of the first transistor of the fourth pixel driving circuit, and the second scan line is configured to provide the scan signal to the gate of the first transistor of the first pixel driving circuit and the gate of the first transistor of the third pixel driving circuit. i is an integer, 1≤i≤M−1, and M is the total number of the pixel driving circuit rows.

In one or more embodiments, the first scan line is configured to provide the scan signal to the gate of the first transistor of the first pixel driving circuit and the gate of the first transistor of the fourth pixel driving circuit, the second scan line is configured to provide the scan signal to the gate of the first transistor of the second pixel driving circuit and the gate of the first transistor of the third pixel driving circuit, D1=D4, and D2=D3.

In one or more embodiments, in a direction perpendicular to the substrate, the projection of the first scan line at least partially overlaps with the gate of the first transistor of the first pixel driving circuit, and the projection of the second scan line at least partially overlaps with the gate of the first transistor of the second pixel driving circuit. In the direction perpendicular to the substrate, the projection of the first scan line at least partially overlaps with the gate of the first transistor of the fourth pixel driving circuit, and the projection of the second scan line at least partially overlaps with the gate of the first transistor of the third pixel driving circuit.

In one or more embodiments, the display panel also includes a shift register circuit. Multiple pixel units are arranged along the first direction to form a pixel driving circuit row, and the shift register circuit is electrically connected to the pixel driving circuit row correspondingly and configured to output the scan signal. In one pixel driving circuit row, the first scan line is configured to provide the scan signal to the gate of the first transistor of the first pixel driving circuit and the gate of the first transistor of the fourth pixel driving circuit, and the second scan line is configured to provide the scan signal to the gate of the first transistor of the second pixel driving circuit and the gate of the first transistor of the third pixel driving circuit.

In one or more embodiments, the display panel also includes a shift register circuit. Multiple pixel units are arranged along the first direction to form pixel driving circuit rows, and the shift register circuit is electrically connected to the pixel driving circuit rows correspondingly and configured to output the scan signal. In an i-th pixel driving circuit row, the first scan line is configured to provide the scan signal to the gate of the first transistor of the first pixel driving circuit and the gate of the first transistor of the fourth pixel driving circuit, and the second scan line is configured to provide the scan signal to the gate of the first transistor of the second pixel driving circuit and the gate of the first transistor of the third pixel driving circuit. In an (i+1)-th pixel driving circuit row, the first scan line is configured to provide the scan signal to the gate of the first transistor of the second pixel driving circuit and the gate of the first transistor of the third pixel driving circuit, and the second scan line is configured to provide the scan signal to the gate of the first transistor of the first pixel driving circuit and the gate of the first transistor of the fourth pixel driving circuit. i is an integer, 1≤i≤M−1, and M is the total number of the pixel driving circuit rows.

In one or more embodiments, the pixel driving circuit also includes a storage capacitor, a second transistor, and a light-emitting element. A first electrode of the first transistor is configured to receive the data signal, and a second electrode of the first transistor is electrically connected to a gate of the drive transistor. A first electrode of the drive transistor is configured to receive a first power signal, and a second electrode of the drive transistor is electrically connected to a first electrode of the second transistor. A second electrode of the second transistor is configured to output a sensing signal. A first plate of the storage capacitor is electrically connected to the gate of the drive transistor, and a second plate of the storage capacitor is electrically connected to the second electrode of the drive transistor. A gate of the second transistor is electrically connected to the gate of the first transistor. The second electrode of the drive transistor is configured to be connected to a first terminal of the light-emitting element, and a second terminal of the light-emitting element is configured to receive a second power signal.

In one or more embodiments, along the second direction, the gate of the second transistor is disposed between the first scan line and the second scan line.

In one or more embodiments, the first scan line is configured to provide the scan signal to the first pixel driving circuit, and the second scan line is configured to provide the scan signal to the second pixel driving circuit. The display panel also includes a first auxiliary connection line and a second auxiliary connection line extending along the second direction. The first auxiliary connection line is configured to connect the gate of the second transistor of the first pixel driving circuit to the first scan line, and the second auxiliary connection line is configured to connect the gate of the second transistor of the second pixel driving circuit to the second scan line.

In one or more embodiments, the display panel also includes a reference voltage line extending along the second direction. The reference voltage line is electrically connected to a second electrode of a second transistor, and at least two pixel units are connected to the same reference voltage line.

In one or more embodiments, the display panel also includes a first power signal line and a second power signal line extending along the second direction. The first power signal line is configured to provide a first power signal to the pixel driving circuit, and the second power signal line is configured to provide a second power signal to the pixel driving circuit. Along the first direction, the reference voltage line and the first power signal line are disposed between adjacent pixel units, or the reference voltage line and the second power signal line are disposed between adjacent pixel units.

In one or more embodiments, along the first direction, the first data line is disposed on a side of the first pixel driving circuit facing away from the second pixel driving circuit, and the second data line is disposed on a side of the third pixel driving circuit facing away from the fourth pixel driving circuit. The display panel also includes a third auxiliary connection line and a fourth auxiliary connection line extending along the first direction. The third auxiliary connection line connects the first data line to a first electrode of the first transistor of the second pixel driving circuit. The fourth auxiliary connection line connects the second data line to a first electrode of the first transistor of the fourth pixel driving circuit.

In one or more embodiments, the display panel includes a first metal layer, a second metal layer, a semiconductor layer, a gate layer, a third metal layer, and a fourth metal layer sequentially disposed on the substrate. The first metal layer is provided with the first plate of the storage capacitor. The second metal layer is provided with the second plate of the storage capacitor. The semiconductor layer is provided with active layers of transistors of the pixel driving circuit. The gate layer is provided with gates of the transistors of the pixel driving circuit. The third metal layer is provided with the first scan line and the second scan line. The fourth metal layer is provided with a first power signal line, a second power signal line, a reference voltage line, the first data line, and the second data line.

In one or more embodiments, the first scan line is configured to provide the scan signal to the first pixel driving circuit, and the second scan line is configured to provide the scan signal to the second pixel driving circuit. In a direction perpendicular to the substrate, the first scan line is electrically connected to the gate of the first transistor of the first pixel driving circuit through a first via, and the second scan line is electrically connected to the gate of the first transistor of the second pixel driving circuit through a second via. The third metal layer also includes a first auxiliary connection line and a second auxiliary connection line extending along the second direction. The first scan line is electrically connected to the gate of the second transistor of the first pixel driving circuit through the first auxiliary connection line. The second scan line is electrically connected to the gate of the second transistor of the second pixel driving circuit through the second auxiliary connection line.

In one or more embodiments, the semiconductor layer of the pixel driving circuit includes a first connection branch and a second connection branch extending along the second direction. In a direction perpendicular to the substrate, an overlapping region between the first connection branch and the gate of the first transistor is a channel of the first transistor. In the direction perpendicular to the substrate, an overlapping region between the second connection branch and the gate of the drive transistor is a channel of the drive transistor, and an overlapping region between the second connection branch and the gate of the second transistor is a channel of the second transistor. A first terminal of the second connection branch is configured to receive the first power signal, and a second terminal of the second connection branch is configured to be connected to the reference voltage line. The second connection branch forms a second node between the channel of the drive transistor and the channel of the second transistor.

In one or more embodiments, the first scan line is configured to provide the scan signal to the first pixel driving circuit, and the second scan line is configured to provide the scan signal to the second pixel driving circuit. In a direction perpendicular to the substrate, the first connection branch of the first pixel driving circuit intersects with the first scan line. In the direction perpendicular to the substrate, the first connection branch of the second pixel driving circuit intersects with both the second scan line and the first scan line.

In one or more embodiments, the first scan line is configured to provide the scan signal to the third pixel driving circuit, and the second scan line is configured to provide the scan signal to the fourth pixel driving circuit. The third metal layer also includes a third auxiliary connection line, a fourth auxiliary connection line, a fifth auxiliary connection line, and a sixth auxiliary connection line extending along the first direction. The fifth auxiliary connection line is configured to connect the first data line to a second terminal of the first connection branch of the first pixel driving circuit. The third auxiliary connection line is configured to connect the first data line to a second terminal of the first connection branch of the second pixel driving circuit. The sixth auxiliary connection line is configured to connect the second data line to a second terminal of the first connection branch of the third pixel driving circuit. The fourth auxiliary connection line is configured to connect the second data line to a second terminal of the first connection branch of the fourth pixel driving circuit.

In one or more embodiments, the first scan line is configured to provide the scan signal to the second pixel driving circuit, and the second scan line is configured to provide the scan signal to the first pixel driving circuit. In the direction perpendicular to the substrate, the first connection branch of the first pixel driving circuit intersects with both the first scan line and the second scan line. In the direction perpendicular to the substrate, the first connection branch of the second pixel driving circuit intersects with both the second scan line and the first scan line.

In one or more embodiments, the third metal layer also includes a third auxiliary connection line and a fourth auxiliary connection line extending along the first direction. The third auxiliary connection line is configured to connect the first data line, a second terminal of the first connection branch of the first pixel driving circuit, and a second terminal of the first connection branch of the second pixel driving circuit. The fourth auxiliary connection line is configured to connect the second data line, a second terminal of the first connection branch of the third pixel driving circuit, and a second terminal of the first connection branch of the fourth pixel driving circuit.

In one or more embodiments, the third metal layer also includes a first power auxiliary line extending along the first direction and a reference auxiliary line extending along the first direction. The first power signal line is electrically connected to the first power auxiliary line through a third via. The first power auxiliary line is electrically connected to the first terminal of the second connection branch through a fourth via. The reference voltage line is electrically connected to the reference auxiliary line through a fifth via. The reference auxiliary line is electrically connected to the second terminal of the second connection branch through a sixth via.

In one or more embodiments, the display panel also includes a fifth metal layer disposed between the second metal layer and the semiconductor layer. The fifth metal layer is provided with an auxiliary gate of the drive transistor. In the direction perpendicular to the substrate, the projection of the auxiliary gate at least partially overlaps with an active layer of the drive transistor of the pixel driving circuit, and the projection of the auxiliary gate at least partially overlaps with the gate of the drive transistor of the pixel driving circuit.

In one or more embodiments, the size of the auxiliary gate of the drive transistor is greater than the size of the gate of the drive transistor.

In one or more embodiments, the third metal layer also includes a crossover portion. The crossover portion is electrically connected to the auxiliary gate through a seventh via. The crossover portion is electrically connected to the second node of the second connection branch through an eighth via. The crossover portion is electrically connected to a first terminal of the first connection branch through a ninth via.

In one or more embodiments, the third metal layer is also provided with a seventh auxiliary connection line, and the second plate of the storage capacitor is provided with an avoidance via. The seventh auxiliary connection line connects the first plate of the storage capacitor and the gate of the drive transistor of the pixel driving circuit through the avoidance via.

In one or more embodiments, along the first direction, the first data line is disposed between the first pixel driving circuit and the second pixel driving circuit, and the second data line is disposed between the third pixel driving circuit and the fourth pixel driving circuit. The display panel also includes an eighth auxiliary connection line and a ninth auxiliary connection line extending along the first direction. The eighth auxiliary connection line connects the first data line to a first electrode of the first transistor of the first pixel driving circuit and to a first electrode of the first transistor of the second pixel driving circuit. The ninth auxiliary connection line connects the second data line to a first electrode of the first transistor of the third pixel driving circuit and to a first electrode of the first transistor of the fourth pixel driving circuit.

In one or more embodiments, the display panel includes a semiconductor layer, and the semiconductor layer of the pixel driving circuit includes a first connection branch and a second connection branch extending along the second direction. In a direction perpendicular to the substrate, an overlapping region between the first connection branch and the gate of the first transistor is a channel of the first transistor. In the direction perpendicular to the substrate, an overlapping region between the second connection branch and a gate of the drive transistor is a channel of the drive transistor, and an overlapping region between the second connection branch and a gate of the second transistor is a channel of the second transistor. In the direction perpendicular to the substrate, the first connection branch of the first pixel driving circuit intersects with both the first scan line and the second scan line, and the first connection branch of the second pixel driving circuit intersects with both the second scan line and the first scan line.

An embodiment of the present disclosure provides a display device including the display panel according to any embodiment of the present disclosure.

### BRIEF DESCRIPTION OF DRAWINGS

FIG. 1 is a diagram illustrating a partial structure of a display panel in the related art.

FIG. 2 is a diagram illustrating the structure of a display panel according to an embodiment of the present disclosure.

FIG. 3 is a diagram illustrating the structure of a pixel driving circuit according to an embodiment of the present disclosure.

FIG. 4 is a diagram illustrating a layout of a pixel driving circuit according to an embodiment of the present disclosure.

FIG. 5 is a diagram illustrating the structure of another display panel according to an embodiment of the present disclosure.

FIG. 6 is a diagram illustrating the structure of another pixel driving circuit according to an embodiment of the present disclosure.

FIG. 7 is a diagram illustrating the structure of another display panel according to an embodiment of the present disclosure.

FIG. 8 is a diagram illustrating the structure of another pixel driving circuit according to an embodiment of the present disclosure.

FIG. 9 is a diagram illustrating a layout of another pixel driving circuit according to an embodiment of the present disclosure.

FIG. 10 is a diagram illustrating the structure of another display panel according to an embodiment of the present disclosure.

FIG. 11 is a diagram illustrating the structure of another pixel driving circuit according to an embodiment of the present disclosure.

FIG. 12 is a diagram illustrating a layout of another pixel driving circuit according to an embodiment of the present disclosure.

FIG. 13 is a diagram illustrating the structure of another display panel according to an embodiment of the present disclosure.

FIG. 14 is a diagram illustrating the structure of another pixel driving circuit according to an embodiment of the present disclosure.

FIG. 15 is a diagram illustrating a layout of another pixel driving circuit according to an embodiment of the present disclosure.

FIG. 16 is a diagram illustrating a partial structure of a display panel according to an embodiment of the present disclosure.

FIG. 17 is a sectional view of the display panel in FIG. 4 taken along line segment a-a'.

FIG. 18 is a diagram illustrating a layout of another pixel driving circuit according to an embodiment of the present disclosure.

FIG. 19 is a diagram illustrating a partial structure of another display panel according to an embodiment of the present disclosure.

FIG. 20 is a diagram illustrating a layout of another pixel driving circuit according to an embodiment of the present disclosure.

FIG. 21 is a diagram illustrating the structure of a display device according to an embodiment of the present disclosure.

### DETAILED DESCRIPTION

Hereinafter, the present disclosure is further described in detail in conjunction with the drawings and embodiments. It is to be understood that the embodiments described herein are only intended to illustrate but not to limit the present disclosure. Additionally, it is to be noted that for ease of description, only part, not all, of the structures related to the present disclosure are illustrated in the drawings.

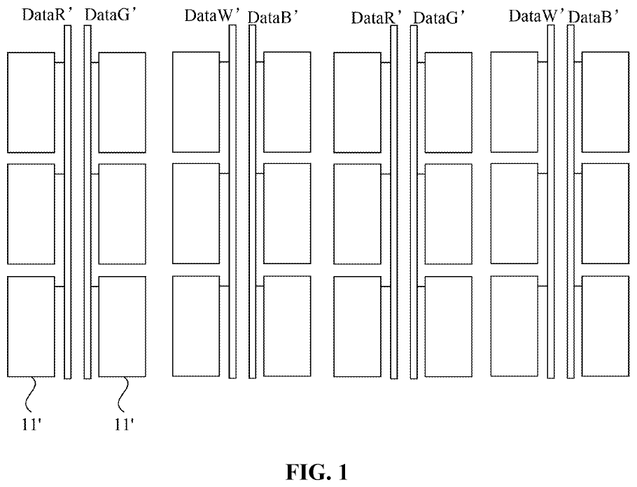

FIG. 1 is a diagram illustrating a partial structure of a display panel in the related art. As can be seen from FIG. 1, the display panel includes multiple pixel driving circuits 11′, and each column of pixel driving circuits 11′ is correspondingly provided with one data line. This is also referred to as single gate line driving (SGLD) technology. FIG. 1 shows data lines DataR′, DataG′, DataW′, and DataB′ corresponding to different columns of pixel driving circuits 11′. However, when implementing SGLD OLED large-screen displays, the inventors found that when the size of the display panel is relatively large or the resolution is relatively high, more data lines are required, resulting in a greater number of driver chips that need to be disposed on the display panel. The costs of driver chips are also relatively high, leading to higher manufacturing costs for the display panel.

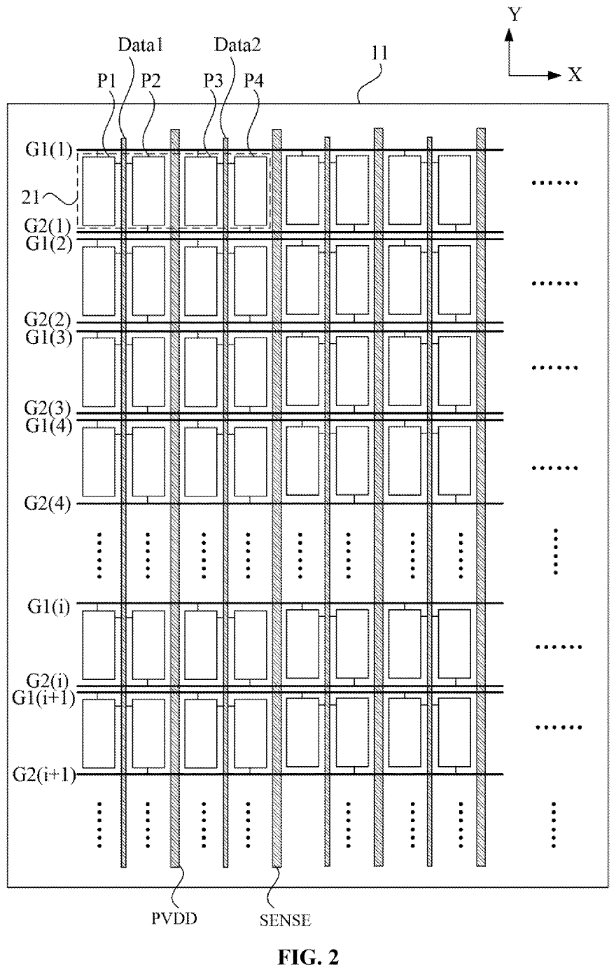

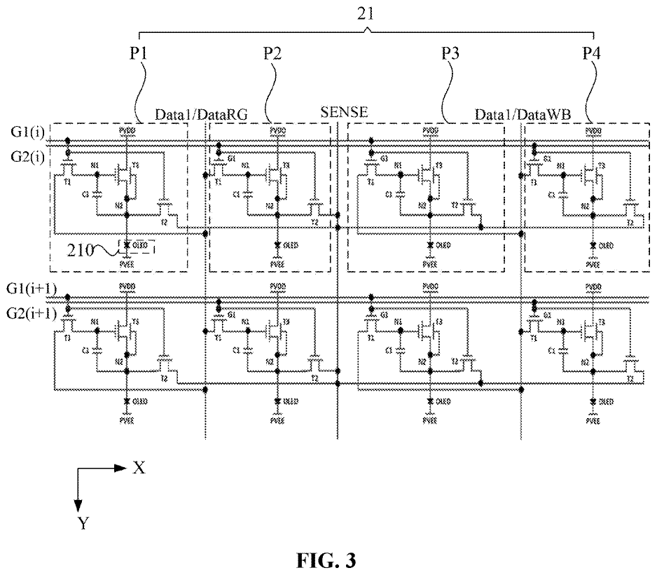

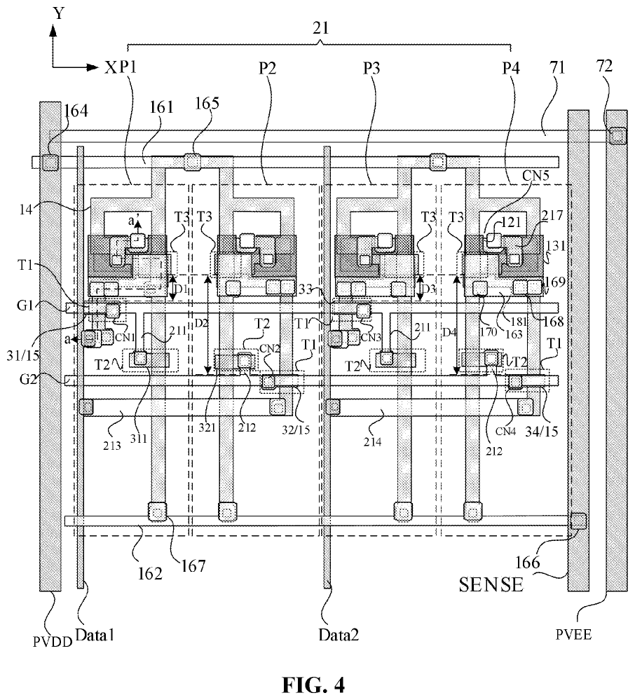

To reduce the manufacturing costs of large-screen displays, the inventors developed dual gate line driving (DGLD) technology, where two columns of pixel driving circuits are scanned using different scan lines, thereby enabling the two columns of pixel driving circuits to share one data line and thus reducing the number of data lines and driver chips in the display panel. However, during the development of DGLD technology, it is necessary to design the layout of the pixel driving circuits to accommodate twice the number of scan lines. Based on the above circumstances, the inventors implemented the display panel according to the embodiments of the present disclosure. FIG. 2 is a diagram illustrating the structure of a display panel according to an embodiment of the present disclosure. FIG. 3 is a diagram illustrating the structure of a pixel driving circuit according to an embodiment of the present disclosure. FIG. 4 is a diagram illustrating a layout of a pixel driving circuit according to an embodiment of the present disclosure. As shown in FIG. 2 to FIG. 4, to reduce the manufacturing costs of the display panel, an embodiment of the present disclosure provides a display panel. The display panel includes a substrate 11, pixel driving circuits, a first data line Data1, a first scan line G1, and a second scan line G2.

A pixel driving circuit at least includes a first transistor T1 and a drive transistor T3. A gate of the first transistor T1 receives a scan signal. The pixel driving circuits at least include a first pixel driving circuit P1 and a second pixel driving circuit P2 arranged along a first direction X.

The first data line Data1 extends along a second direction Y. The first data line Data1 provides a data signal to the first pixel driving circuit P1 and the second pixel driving circuit P2. The first direction X intersects with the second direction Y.

The first scan line G1 and the second scan line G2 extend along the first direction X. The first scan line G1 provides the scan signal to a gate of a first transistor T1 of one of the first pixel driving circuit P1 or the second pixel driving circuit P2, and the second scan line G2 provides the scan signal to a gate of a first transistor T1 of the other of the first pixel driving circuit P1 and the second pixel driving circuit P2.

Along the second direction Y, the distance from the first transistor T1 of the first pixel driving circuit P1 to a corresponding drive transistor T3 of the first pixel driving circuit P1 is D1, the distance from the first transistor T1 of the second pixel driving circuit P2 to a corresponding drive transistor T3 of the second pixel driving circuit P2 is D2, and |D1−D2|>0.

In the embodiments of the present disclosure, the display panel includes the first pixel driving circuit and the second pixel driving circuit arranged along the first direction, as well as the first data line extending along the second direction. The same first data line may provide data signals to the first pixel driving circuit and the second pixel driving circuit. The display panel also includes the first scan line and the second scan line extending along the first direction. The first scan line provides the scan signal to the gate of the first transistor of the first pixel driving circuit, and the second scan line provides the scan signal to the gate of the first transistor of the second pixel driving circuit. In this embodiment, the first pixel driving circuit and the second pixel driving circuit share one first data line and adopt a dual gate line driving method, thereby reducing the number of data lines in the display panel, further reducing the number of data signals provided by driver chips on the border of the display panel, and lowering power consumption and manufacturing costs of the display panel. Moreover, since the first pixel driving circuit and the second pixel driving circuit are provided with different scan lines, the display panel can maintain a relatively high resolution. Along the second direction, the distance D1 between the first transistor and the drive transistor in the first pixel driving circuit differs from the distance D2 between the first transistor and the drive transistor in the second pixel driving circuit, which reduces crossover arrangements in each pixel driving circuit, thereby reducing the wiring complexity and manufacturing costs of the display panel.

The above is the core idea of the present disclosure, and the technical solutions in the embodiments of the present disclosure are described clearly and completely hereinafter in conjunction with the drawings in the embodiments of the present disclosure. Based on the embodiments of the present disclosure, all other embodiments obtained by those of ordinary skill in the art without creative work are within the scope of the present disclosure.

As shown in FIG. 2, the display panel includes a substrate 11 and a pixel driving circuit layer disposed on the substrate 11. The substrate 11 may be a rigid substrate formed of a material such as glass or a flexible substrate formed of a material such as polyimide. The pixel driving circuit layer includes multiple metal layers. In a plane parallel to the substrate 11, the pixel driving circuit layer includes pixel driving circuits arranged in an array. As shown in FIG. 4, each pixel driving circuit at least includes a first transistor T1 and a drive transistor T3. The gate of the first transistor T1 may receive a scan signal for turning the first transistor T1 on or off according to the scan signal, thereby controlling the potential signal at the gate of the drive transistor T3 and thus controlling the magnitude of the output current of the drive transistor T3. The display panel is also provided with a light-emitting element on a side of the pixel driving circuit layer facing away from the substrate 11. The light-emitting element may be an OLED device as shown in FIG. 3 or may be another device such as a Mini LED or a Micro LED, which is not specifically limited by this embodiment. The output current of the drive transistor T3 flows through the light-emitting element to control light emission of the light-emitting element. For example, the first transistor T1 may receive a data signal, thereby writing the data signal to the control terminal of the drive transistor T3, achieving control over the magnitude of the current flowing through the light-emitting element, and thus controlling the light-emitting element to emit light of a desired brightness to achieve image display.

As shown in FIG. 2 to FIG. 4, the pixel driving circuits at least include a first pixel driving circuit P1 and a second pixel driving circuit P2 arranged along the first direction X, as well as a first data line Data1 extending along the second direction Y. The first direction X intersects with the second direction Y. For example, as shown in FIG. 2 and FIG. 3, the first direction X is perpendicular to the second direction Y. In this embodiment, the pixel driving circuits may be arranged in rows along the first direction X and in columns along the second direction Y. It should be noted that the same first data line Data1 may be separately connected to the first pixel driving circuit P1 and the second pixel driving circuit P2 to provide data signals to the first pixel driving circuit P1 and the second pixel driving circuit P2. At least the first pixel driving circuit P1 and the second pixel driving circuit P2 are disposed along the first direction X to enable the sharing of the first data line Data1. To enable independent light emission and display of the first pixel driving circuit P1 and the second pixel driving circuit P2, this embodiment provides a first scan line G1 and a second scan line G2 extending along the first direction X. As shown in FIG. 2, when the pixel driving circuits are arranged in rows along the first direction X, each row of pixel driving circuits is correspondingly provided with the first scan line G1 and the second scan line G2. For example, along the second direction Y, the first row of pixel driving circuits is provided with a first scan line G1(1) and a second scan line G2(1), the second row is provided with a first scan line G1(2) and a second scan line G2(2), the third row is provided with a first scan line G1(3) and a second scan line G2(3), the fourth row is provided with a first scan line G1(4) and a second scan line G2(4), and so on. An i-th row of pixel driving circuits is provided with a first scan line G1(i) and a second scan line G2(i), an (i+1)-th row of pixel driving circuits is provided with a first scan line G1(i+1) and a second scan line G2(i+1), until an M-th row of pixel driving circuits is provided with a first scan line G1(M) and a second scan line G2(M). M may be the total number of rows of pixel driving circuits. It should be noted that the arrangement order of the scan lines connected to each row of pixel driving circuits is either the first scan line G1 followed by the second scan line G2, or the second scan line G2 followed by the first scan line G1. In this embodiment, the arrangement order of the first scan line G1 followed by the second scan line G2 is used as an example for illustration. In this embodiment, the first scan line G1 may provide the scan signal to the gate of the first transistor T1 of the first pixel driving circuit P1, and the second scan line G2 may provide the scan signal to the gate of the first transistor T1 of the second pixel driving circuit P2. Alternatively, the first scan line G1 may provide the scan signal to the gate of the first transistor T1 of the second pixel driving circuit P2, and the second scan line G2 may provide the scan signal to the gate of the first transistor T1 of the first pixel driving circuit P1. The first scan line G1 and the second scan line G2 sequentially output active pulses to scan the first pixel driving circuit P1 and the second pixel driving circuit P2 in a time-division manner. During the time period when the first scan line G1 outputs an active pulse, the first data line Data1 provides a data signal to one of the first pixel driving circuit P1 and the second pixel driving circuit P2; during the time period when the second scan line G2 outputs an active pulse, the first data line Data1 provides a data signal to the other of the first pixel driving circuit P1 and the second pixel driving circuit P2, which is the DGLD technology.

As shown in FIG. 4, FIG. 4 is a schematic diagram illustrating the layout of a pixel driving circuit implementing DGLD technology according to this embodiment. Along the second direction Y, the distance between the first transistor T1 of the first pixel driving circuit P1 and the drive transistor T3 of the first pixel driving circuit P1 is set as D1, and the distance between the first transistor T1 of the second pixel driving circuit P2 and the drive transistor T3 of the second pixel driving circuit P2 is set as D2. Since the first scan line G1 and the second scan line G2 are sequentially arranged along the second direction Y, a certain spacing exists between the first scan line G1 and the second scan line G2 along the second direction Y. The positions of the first transistor T1 of the first pixel driving circuit P1 and the first transistor T1 of the second pixel driving circuit P2 are set differently so that adaptive connections to the corresponding scan lines are achieved, crossover arrangements in each pixel driving circuit are reduced, and the wiring complexity and manufacturing costs of the display panel are reduced. For example, in this embodiment, the first transistor T1 of the first pixel driving circuit P1 connected to the first scan line G1 is disposed adjacent to the first scan line G1, and the first transistor T1 of the second pixel driving circuit P2 connected to the second scan line G2 is disposed adjacent to the second scan line G2. This configuration can eliminate or shorten the connection wire between the first transistor T1 and the scan line connected to the first transistor T1. That is, the values of D1 and D2 are controlled to be different so that the first transistor T1 of the first pixel driving circuit P1 is positioned adjacent to the first scan line G1, and the first transistor T1 of the second pixel driving circuit P2 is positioned adjacent to the second scan line G2.

It should be noted that each transistor in the pixel driving circuit includes a channel formed by an overlap between an active layer (semiconductor layer) and a gate, as well as a first electrode and a second electrode connected to the channel. When the transistor is turned on, current sequentially flows through the first electrode, the channel, and the second electrode. In this embodiment, the spacing between the channel of the first transistor T1 of the first pixel driving circuit P1 and the channel of the drive transistor T3 of the first pixel driving circuit P1 is used as the distance D1 between the first transistor T1 and the drive transistor T3 of the second pixel driving circuit P2, and the spacing between the channel of the first transistor T1 of the second pixel driving circuit P2 and the channel of the drive transistor T3 of the second pixel driving circuit P2 is used as the distance D2 between the first transistor T1 and the drive transistor T3 of the second pixel driving circuit P2. As shown in FIG. 4, when the first scan line G1 is connected to the first pixel driving circuit P1 and the second scan line G2 is connected to the second pixel driving circuit P2, the channel of the first transistor T1 of the first pixel driving circuit P1 is disposed adjacent to the first scan line G1, and the channel of the first transistor T1 of the second pixel driving circuit P2 is disposed adjacent to the second scan line G2. In one or more embodiments, as shown in FIG. 4, when the drive transistor T3, the first scan line G1, and the second scan line G2 are sequentially arranged along the second direction Y, D2>D1. Of course, when the drive transistor T3, the second scan line G2, and the first scan line G1 are sequentially arranged along the second direction Y, D1>D2. Under different arrangement orders, the magnitude relationship between D1 and D2 varies. In this embodiment, the magnitude relationship between D1 and D2 is not specifically limited, as long as the values of D1 and D2 are different to ensure the proximity to respective connected scan lines.

In one or more embodiments, as shown in FIG. 4, the channel of the first transistor T1 o the first pixel driving circuit P1 may at least partially overlap with the first scan line G1, thereby avoiding the need to provide a larger gate for the first transistor T1 of the second pixel driving circuit P2 or the need to provide a longer connection line for the first scan line G1 along the second direction Y. Similarly, the channel of the first transistor T1 of the second pixel driving circuit P2 may at least partially overlap with the second scan line G2, thereby avoiding the need to provide a larger gate for the first transistor T1 of the second pixel driving circuit P2 or the need to provide a longer extension line for the second scan line G2 along the second direction Y. In this embodiment, DGLD technology is adopted so that the number of scan lines and driver chips in the display panel is reduced. Moreover, along the second direction Y, the distance D1 between the first transistor T1 of the first pixel driving circuit P1 and the drive transistor T3 of the first pixel driving circuit P1 is controlled to differ from the distance D2 between the first transistor T1 of the second pixel driving circuit P2 and the drive transistor T3 of the second pixel driving circuit P2. This configuration helps the first transistor T1 of the first pixel driving circuit P1 be disposed adjacent to the first scan line G1 and the first transistor T1 of the second pixel driving circuit P2 be disposed adjacent to the second scan line G2, thereby reducing crossover arrangements in each pixel driving circuit and reducing the wiring complexity and manufacturing costs of the display panel.

With continued reference to FIG. 2 to FIG. 4, in one or more embodiments, the pixel driving circuits may also include a third pixel driving circuit P3 and a fourth pixel driving circuit P4 arranged along the first direction X. Along the first direction X, the first pixel driving circuit P1, the second pixel driving circuit P2, the third pixel driving circuit P3, and the fourth pixel driving circuit P4 constitute a pixel unit 21. The display panel also includes a second data line Data2 extending along the second direction Y. The second data line Data2 is configured to provide a data signal to the third pixel driving circuit P3 and the fourth pixel driving circuit P4. Along the second direction Y, the distance from the first transistor T1 of the third pixel driving circuit P3 to a corresponding drive transistor T3 of the third pixel driving circuit P3 is D3, the distance from the first transistor T1 of the fourth pixel driving circuit P4 to a corresponding drive transistor T3 of the fourth pixel driving circuit P4 is D4, and |D3−D4|>0.

As shown in FIG. 4, in this embodiment, at least the first pixel driving circuit P1, the second pixel driving circuit P2, the third pixel driving circuit P3, and the fourth pixel driving circuit P4 are disposed along the first direction X, and the first pixel driving circuit P1, the second pixel driving circuit P2, the third pixel driving circuit P3, and the fourth pixel driving circuit P4 may constitute a pixel unit 21. For example, the first pixel driving circuit P1 may drive a red light-emitting element, the second pixel driving circuit P2 may drive a green light-emitting element, the third pixel driving circuit P3 may drive a white light-emitting element, and the fourth pixel driving circuit P4 may drive a blue light-emitting element. The display panel may include pixel units 21 arranged in an array to achieve image display on a large screen. The same first data line Data1 may be separately connected to the first pixel driving circuit P1 and the second pixel driving circuit P2 to separately provide data signals to the first pixel driving circuit P1 and the second pixel driving circuit P2. Similarly, the same second data line Data2 may be separately connected to the third pixel driving circuit P3 and the fourth pixel driving circuit P4 to separately provide data signals to the third pixel driving circuit P3 and the fourth pixel driving circuit P4. Likewise, since the first transistor T1 of the third pixel driving circuit P3 and the first transistor T1 of the fourth pixel driving circuit P4 need to be connected to different scan lines to achieve time-division scanning, in this embodiment, the distance between the first transistor T1 of the third pixel driving circuit P3 and the drive transistor T3 of the third pixel driving circuit P3 is set as D3, the distance between the first transistor T1 of the fourth pixel driving circuit P4 and the drive transistor T3 of the fourth pixel driving circuit P4 is set as D4, and D3 and D4 are controlled to have different values. Consequently, the first transistor T1 of the third pixel driving circuit P3 is disposed adjacent to a scan line connected to the first transistor T1 of the third pixel driving circuit P3, and the first transistor T1 of the fourth pixel driving circuit P4 is disposed adjacent to a scan line connected to the first transistor T1 of the fourth pixel driving circuit P4. In this embodiment, the spacing between the channel of the first transistor T1 of the third pixel driving circuit P3 and the channel of the drive transistor T3 of the third pixel driving circuit P3 is used as the distance D3 between the first transistor T1 and the drive transistor T3 of the third pixel driving circuit P3, and the spacing between the channel of the first transistor T1 of the fourth pixel driving circuit P4 and the channel of the drive transistor T3 of the fourth pixel driving circuit P4 is used as the distance D4 between the first transistor T1 and the drive transistor T3 of the fourth pixel driving circuit P4. In other words, the channel of the first transistor T1 of the third pixel driving circuit P3 is disposed adjacent to the scan line connected to the channel of the first transistor T1 of the third pixel driving circuit P3, and the channel of the first transistor T1 of the fourth pixel driving circuit P4 is disposed adjacent to the scan line connected to the channel of the first transistor T1 of the fourth pixel driving circuit P4. The configuration in this embodiment can avoid the need to provide a larger gate for the first transistor T1 or the need to provide a longer extension line along the second direction Y for the scan line connected to the first transistor T1, thereby reducing crossover arrangements in each pixel driving circuit and reducing the wiring complexity and manufacturing costs of the display panel.

In one or more embodiments, the first scan line G1 may be configured to provide the scan signal to the gate of a first transistor T1 in one of the third pixel driving circuit P3 or the fourth pixel driving circuit P4, and the second scan line G2 may be configured to provide the scan signal to the gate of a first transistor T1 in the other of the third pixel driving circuit P3 or the fourth pixel driving circuit P4. In this embodiment, the first scan line G1 and the second scan line G2 extending along the first direction X are provided. In this embodiment, the first scan line G1 may provide the scan signal to the gate of the first transistor T1 of the third pixel driving circuit P3, and the second scan line G2 may provide the scan signal to the gate of the first transistor T1 of the fourth pixel driving circuit P4. Alternatively, the first scan line G1 may provide the scan signal to the gate of the first transistor T1 of the fourth pixel driving circuit P4, and the second scan line G2 may provide the scan signal to the gate of the first transistor T1 of the third pixel driving circuit P3. The first scan line G1 and the second scan line G2 sequentially output active pulses to scan the third pixel driving circuit P3 and the fourth pixel driving circuit P4 in a time-division manner. During the time period when the first scan line G1 outputs an active pulse, the second data line Data2 provides a data signal to one of the third pixel driving circuit P3 and the fourth pixel driving circuit P4. During the time period when the second scan line G2 outputs an active pulse, the second data line Data2 provides a data signal to the other of the third pixel driving circuit P3 and the fourth pixel driving circuit P4. Since the first scan line G1 and the second scan line G2 are sequentially arranged along the second direction Y, a certain spacing exists between the first scan line G1 and the second scan line G2 along the second direction Y. The positions of the first transistor T1 of the third pixel driving circuit P3 and the first transistor T1 of the fourth pixel driving circuit P4 are set differently so that adaptive connections to the corresponding scan lines are achieved, crossover arrangements in each pixel driving circuit are reduced, and the wiring complexity and manufacturing costs of the display panel are reduced. For example, in this embodiment, the first transistor T1 of the third pixel driving circuit P3 connected to the first scan line G1 is disposed adjacent to the first scan line G1, and the first transistor T1 of the fourth pixel driving circuit P4 connected to the second scan line G2 is disposed adjacent to the second scan line G2. This configuration can eliminate or shorten the connection wire between the first transistor T1 and the scan line connected to the first transistor T1. That is, the values of D3 and D4 are controlled to be different so that the channel of the first transistor T1 of the third pixel driving circuit P3 is positioned adjacent to the first scan line G1, and the channel of the first transistor T1 of the fourth pixel driving circuit P4 is positioned adjacent to the second scan line G2. In an embodiment, as shown in FIG. 4, when the drive transistor T3, the first scan line G1, and the second scan line G2 are sequentially arranged along the second direction Y, D4>D3. Of course, when the drive transistor T3, the second scan line G2, and the first scan line G1 are sequentially arranged along the second direction Y, D3>D4. Under different arrangement orders, the magnitude relationship between D3 and D4 varies. In this embodiment, the magnitude relationship between D3 and D4 is not specifically limited, as long as the values of D3 and D4 are different to ensure the proximity to respective connected scan lines.

As shown in FIG. 4, in one or more embodiments, the first scan line G1 is configured to provide the scan signal to the gate of the first transistor T1 of the first pixel driving circuit P1 and the gate of the first transistor T1 of the third pixel driving circuit P3, and the second scan line G2 is configured to provide the scan signal to the gate of the first transistor T1 of the second pixel driving circuit P2 and the gate of the first transistor T1 of the fourth pixel driving circuit P4, D1=D3, and D2=D4. When D1=D3, the first transistor T1 of the first pixel driving circuit P1 and the first transistor T1 of the third pixel driving circuit P3, both connected to the first scan line G1, are disposed adjacent to the first scan line G1. This configuration facilitates the sharing of the first scan line G1 between the first pixel driving circuit P1 and the third pixel driving circuit P3 without the need to provide an additional scan line for the third pixel driving circuit P3, thereby simplifying the wiring arrangement of the pixel driving circuits. Similarly, when D2=D4, the first transistor T1 of the second pixel driving circuit P2 and the first transistor T1 of the fourth pixel driving circuit P4, both connected to the second scan line G2, are disposed adjacent to the second scan line G2. This facilitates the sharing of the second scan line G2 between the second pixel driving circuit P2 and the fourth pixel driving circuit P4 without the need to provide an additional scan line for the fourth pixel driving circuit P4, thereby simplifying the wiring arrangement of the pixel driving circuits. In addition, when D1=D3, the layout of the first transistor T1 and the drive transistor T3 in the first pixel driving circuit P1 may be the same as that in the third pixel driving circuit P3. Similarly, when D2=D4, the layout of the second pixel driving circuit P2 may be the same as that of the fourth pixel driving circuit P4. In this embodiment, the repeated layouts of the pixel driving circuits simplify the wiring arrangement of the pixel driving circuit layer and reduce the process complexity of the display panel. In one or more embodiments, the channel of the first transistor T1 of the first pixel driving circuit P1 may at least partially overlap with the first scan line G1, the channel of the first transistor T1 of the third pixel driving circuit P3 may at least partially overlap with the first scan line G1, the channel of the first transistor T1 of the second pixel driving circuit P2 may at least partially overlap with the second scan line G2, and the channel of the first transistor T1 of the fourth pixel driving circuit P4 may at least partially overlap with the second scan line G2, thereby avoiding the need to provide a larger gate for the first transistor T1 or the need to provide a longer connection line for the scan line along the second direction Y. This configuration reduces crossover arrangements in each pixel driving circuit and reduces the wiring complexity and manufacturing costs of the display panel.

With continued reference to FIG. 4, in one or more embodiments, in a direction perpendicular to the plane where the substrate 11 is located, the projection of the first scan line G1 may at least partially overlap with the gate 31 of the first transistor T1 of the first pixel driving circuit P1, and the projection of the second scan line G2 may at least partially overlap with the gate 32 of the first transistor T1 of the second pixel driving circuit P2. In the direction perpendicular to the plane where the substrate 11 is located, the projection of the first scan line G1 may at least partially overlap with the gate 33 of the first transistor T1 of the third pixel driving circuit P3, and the projection of the second scan line G2 may at least partially overlap with the gate 34 of the first transistor T1 of the fourth pixel driving circuit P4.

In this embodiment, the gates of the transistors and the scan lines are located in different metal layers. With reference to FIG. 4, in this embodiment, a gate layer 15 is also formed between the semiconductor layer 14 and the scan lines. The gate layer 15 overlaps with a semiconductor to form the channels of the transistors, and the gate layer 15 is also electrically connected to corresponding scan lines to acquire scan signals. Of course, in this embodiment, the channels may also be formed in the overlapping regions between the scan lines and the semiconductor layer, without a gate layer being provided. The formation method of the channels is not specifically limited by this embodiment, but the layout diagrams of the pixel driving circuits are described in detail using the circuit structure provided with the gate layer 15 as an example.

As shown in FIG. 4, in the direction perpendicular to the substrate, the overlapping portion between the gate 31 of the first transistor T1 of the first pixel driving circuit P1 and the semiconductor layer 14 forms the channel of the first transistor T1 of the first pixel driving circuit P1. The projection of the first scan line G1 may at least partially overlap with the gate 31 of the first transistor T1 of the first pixel driving circuit P1. This configuration facilitates a direct electrical connection of the first scan line G1 to the gate 31 of the first transistor T1 through a first via CN1 perpendicular to the substrate and avoids the need to provide an additional extension line on the first scan line G1 to connect to the gate 31. Similarly, the overlapping portion between the gate 32 of the first transistor T1 of the second pixel driving circuit P2 and the semiconductor layer 14 forms the channel of the first transistor T1 of the second pixel driving circuit P2. The projection of the second scan line G2 may at least partially overlap with the gate 32 of the first transistor T1 of the second pixel driving circuit P2. This configuration facilitates a direct electrical connection of the second scan line G2 to the gate 32 of the first transistor T1 through a second via CN2 perpendicular to the substrate avoids the need to provide an additional extension line on the second scan line G2 to connect to the gate 32. In addition, the projection of the first scan line G1 may at least partially overlap with the gate 33 of the first transistor T1 of the third pixel driving circuit P3, which facilitates a direct electrical connection of the first scan line G1 to the gate 33 of the first transistor T1 through a via CN3 perpendicular to the substrate. The projection of the second scan line G2 may at least partially overlap with the gate 34 of the first transistor T1 of the fourth pixel driving circuit P4, which facilitates a direct electrical connection of the second scan line G2 to the gate 34 of the first transistor T1 through a via CN4 perpendicular to the substrate. In this embodiment, the scan lines overlap with the gates of the transistors to which the scan lines are connected, thereby facilitating the reduction of the arrangement of extension lines on the scan line layer, reducing the complexity of the layers, and reducing the process difficulty of the display panel.

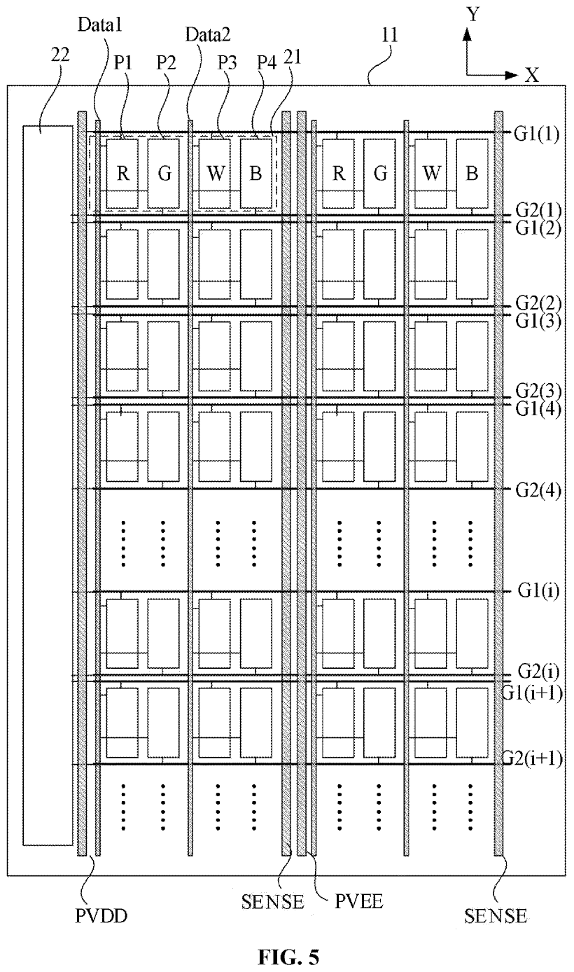

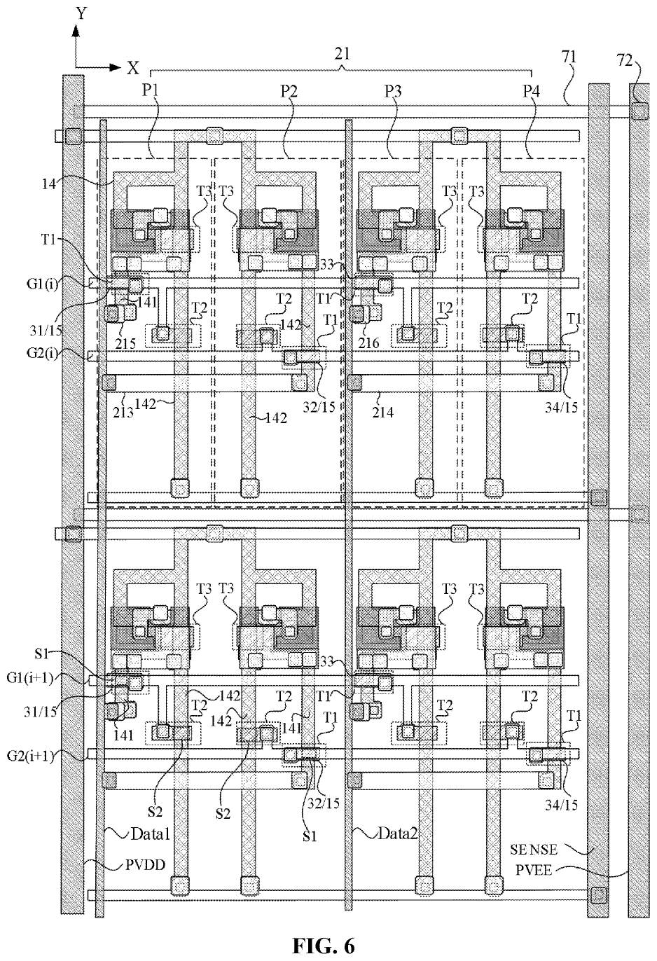

FIG. 5 is a diagram illustrating the structure of another display panel according to an embodiment of the present disclosure. FIG. 6 is a diagram illustrating the structure of another pixel driving circuit according to an embodiment of the present disclosure. With reference to FIG. 3, FIG. 5, and FIG. 6, in one or more embodiments, the display panel may also include a shift register circuit 22. Multiple pixel units 21 are arranged along the first direction X to form a pixel driving circuit row. The shift register circuit 22 is electrically connected to the pixel driving circuit row correspondingly and is configured to output the scan signal. In each pixel driving circuit row, the first scan line G1 is configured to provide the scan signal to the gate of the first transistor T1 of the first pixel driving circuit P1 and the gate of the first transistor T1 of the third pixel driving circuit P3, and the second scan line G2 is configured to provide the scan signal to the gate of the first transistor T1 of the second pixel driving circuit P2 and the gate of the first transistor T1 of the fourth pixel driving circuit P4.

In one or more embodiments, the shift register circuit 22 may include cascaded first shift register units that provide scan signals to the first scan line G1, and cascaded second shift register units that provide scan signals to the second scan line G2. The first shift register units may be in a one-to-one correspondence with the pixel driving circuit rows, thereby providing scan signals to the first scan line G1 of a corresponding pixel driving circuit row. The second shift register units may be in a one-to-one correspondence with the pixel driving circuit rows, thereby providing scan signals to the second scan line G2 of a corresponding pixel driving circuit row. Of course, the shift register circuit 22 may also include cascaded third shift register units that simultaneously provide scan signals to the first scan line G1 and the second scan line G2, which is not specifically limited in this embodiment. As shown in FIG. 6, in each row of pixel driving circuits from the first row of pixel driving circuit to the M-th row of pixel driving circuit, the first scan line G1 outputs the scan signal from a corresponding first shift register unit to the first pixel driving circuit P1 and the third pixel driving circuit P3, and the second scan line G2 outputs the scan signal from a corresponding second shift register unit to the second pixel driving circuit P2 and the fourth pixel driving circuit P4. As shown in FIG. 6, the scanning order of the scan lines corresponding to each row of pixel driving circuits is sequentially the first scan line G1 followed by the second scan line G2. The display panel in this embodiment can achieve the row-by-row DGLD driving of the pixel driving circuits. The first data line Data1 and the second data line Data2 provide data signals to different pixel driving circuits in a time-division manner, thereby halving the number of the first data lines Data1 and the second data lines Data2 in the entire display panel, reducing the number of driver chips, and lowering the manufacturing costs of the display panel, especially the manufacturing costs of OLED TV display panels.

In one or more embodiments, the first pixel driving circuit P1 drives a red light-emitting element R, the second pixel driving circuit P2 drives a green light-emitting element G, the third pixel driving circuit P3 drives a white light-emitting element W, and the fourth pixel driving circuit P4 drives a blue light-emitting element B. The red light-emitting element R and the green light-emitting element G share the first data line Data1 (which may be referred to as DataRG in this example). Since the difference between a data signal required for light emission of the red light-emitting element R and a data signal required for light emission of the green light-emitting element G is relatively small, no positive-negative inversion of the data signal exists. Because the active pulse of the first scan line G1 is adjacent to the active pulse of the second scan line G2 with a short time interval, a relatively large difference in the data signals output by the first data line Data1 during two adjacent active pulses can be avoided in this embodiment, thereby avoiding high power consumption and preventing rapidly changing data signals from affecting display effect of the display effect of the light-emitting elements. In this embodiment, the red light-emitting element and the green light-emitting element share the first data line Data1. Similarly, the white light-emitting element W and the blue light-emitting element B share the second data line Data2 (DataWB), which can also avoid large changes in the data signal output by the second data line Data2 within a short time, effectively reduce power consumption, and improve the quality of image display. Specifically, in this embodiment, during the time period when the first scan line G1 outputs an active pulse, the first data line Data1 provides a data signal to the first pixel driving circuit P1, and the second data line Data2 provides a data signal to the third pixel driving circuit P3. During the time period when the second scan line G2 outputs an active pulse, the first data line Data1 provides a data signal to the second pixel driving circuit P2, and the second data line Data2 provides a data signal to the fourth pixel driving circuit P4.

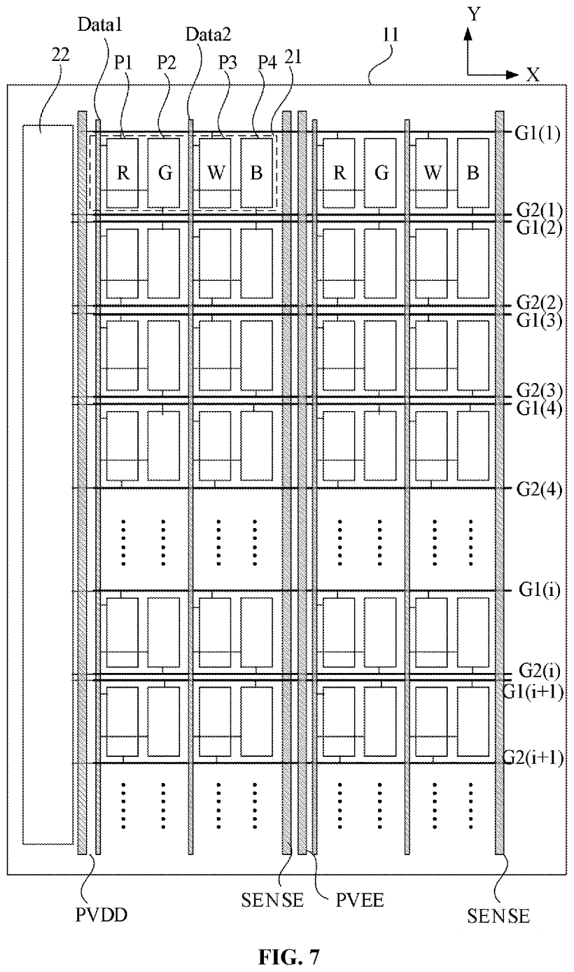

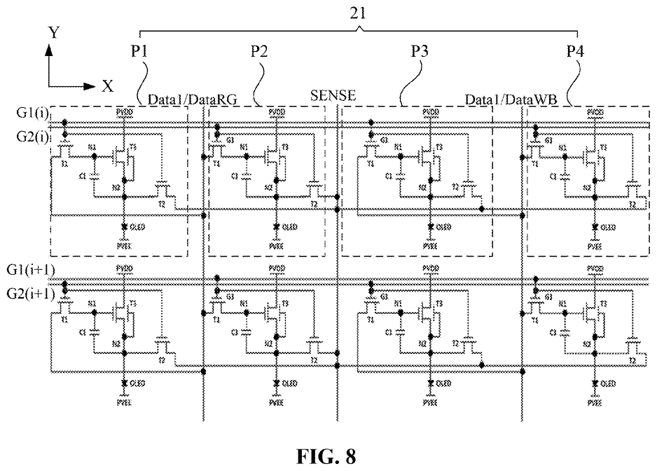

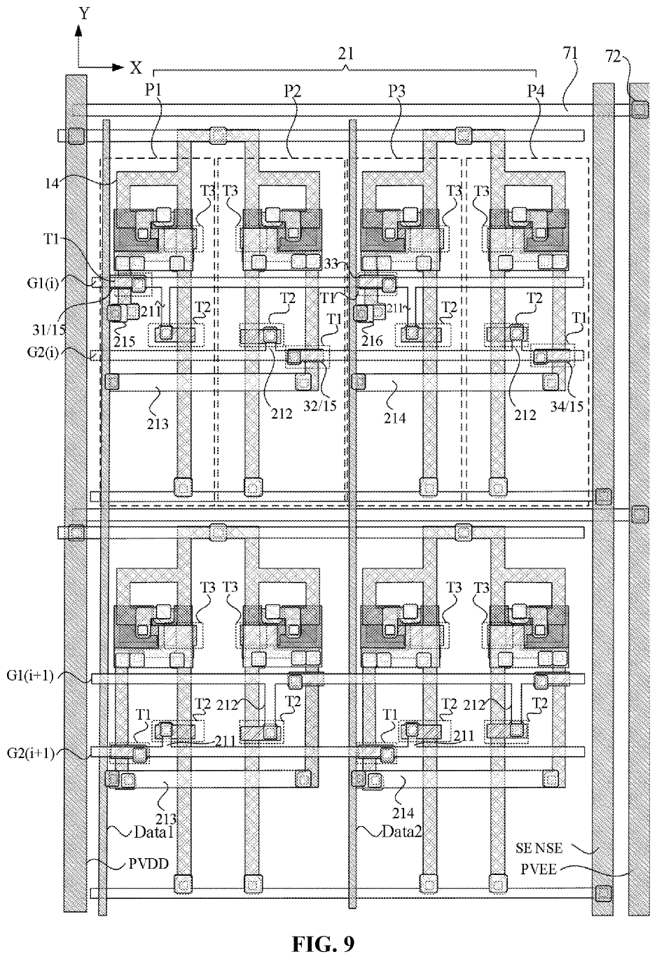

FIG. 7 is a diagram illustrating the structure of another display panel according to an embodiment of the present disclosure. FIG. 8 is a diagram illustrating the structure of another pixel driving circuit according to an embodiment of the present disclosure. FIG. 9 is a diagram illustrating a layout of another pixel driving circuit according to an embodiment of the present disclosure. In one or more embodiments, the display panel may also include a shift register circuit 22. Multiple pixel units 21 are arranged along the first direction X to form pixel driving circuit rows. The shift register circuit 22 is electrically connected to the pixel driving circuit rows correspondingly and is configured to output the scan signal. In an i-th pixel driving circuit row, the first scan line G1(i) is configured to provide the scan signal to the gate of the first transistor T1 of the first pixel driving circuit P1 and the gate of the first transistor T1 of the third pixel driving circuit P3, and the second scan line G2(i) is configured to provide the scan signal to the gate of the first transistor T1 of the second pixel driving circuit P2 and the gate of the first transistor T1 of the fourth pixel driving circuit P4. In an (i+1)-th pixel driving circuit row, the first scan line G1(i+1) is configured to provide the scan signal to the gate of the first transistor T1 of the second pixel driving circuit P2 and the gate of the first transistor T1 of the fourth pixel driving circuit P4, and the second scan line G2(i+1) is configured to provide the scan signal to the gate of the first transistor T1 of the first pixel driving circuit P1 and the gate of the first transistor T1 of the third pixel driving circuit P3. Here, i is an integer, 1≤i≤M−1, and M is the total number of pixel driving circuit rows.

FIG. 5 is compared with FIG. 7, both of which show display panels in which the first pixel driving circuit P1 and the third pixel driving circuit P3 share one scan line, and the second pixel driving circuit P2 and the fourth pixel driving circuit P4 share one scan line. However, the difference lies in the following: In the solution of FIG. 5, the first scan line G1(i) of the i-th pixel driving circuit row is used to provide scan signals to the first pixel driving circuit P1 and the third pixel driving circuit P3, and the first scan line G1(i+1) of the (i+1)-th pixel driving circuit row is also used to provide scan signals to the first pixel driving circuit P1 and the third pixel driving circuit P3. In contrast, in the solution shown in FIG. 7, in the i-th pixel driving circuit row, the first scan line G1(i) is used to provide scan signals to the first pixel driving circuit P1 and the third pixel driving circuit P3, and the second scan line G2(i) is used to provide scan signals to the second pixel driving circuit P2 and the fourth pixel driving circuit P4; in the (i+1)-th pixel driving circuit row, the first scan line G1(i+1) is used to provide scan signals to the second pixel driving circuit P2 and the fourth pixel driving circuit P4, and the second scan line G2(i+1) is used to provide scan signals to the first pixel driving circuit P1 and the third pixel driving circuit P3. Therefore, in this embodiment, two adjacent rows of pixel driving circuits are used as a unit. In the i-th pixel driving circuit row, the first scan line G1(i) is used to provide scan signals to the first pixel driving circuit P1 and the third pixel driving circuit P3. In the (i+1)-th pixel driving circuit row, the first scan line G1(i+1) is used to provide scan signals to the second pixel driving circuit P2 and the fourth pixel driving circuit P4. Consequently, in two adjacent rows of pixel driving circuits, the first pixel driving circuit P1, the third pixel driving circuit P3, the second pixel driving circuit P2, and the fourth pixel driving circuit P4 are all effectively driven by the first scan line G1. The first scan line G1(i) and the first scan line G1(i+1) are generated by cascading the same shift register, resulting in a small difference in the provided scan signals. This configuration effectively reduces issues such as mura and improves the display effect of the display panel. Similarly, the second scan line G2(i) and the second scan line G2(i+1) are generated by cascading the same shift register, resulting in a small difference in the provided scan signals. Likewise, two adjacent rows of pixel driving circuits may be used as a unit to effectively drive the first pixel driving circuit P1, the third pixel driving circuit P3, the second pixel driving circuit P2, and the fourth pixel driving circuit P4 using the second scan line G2, thereby preventing display non-uniformity.

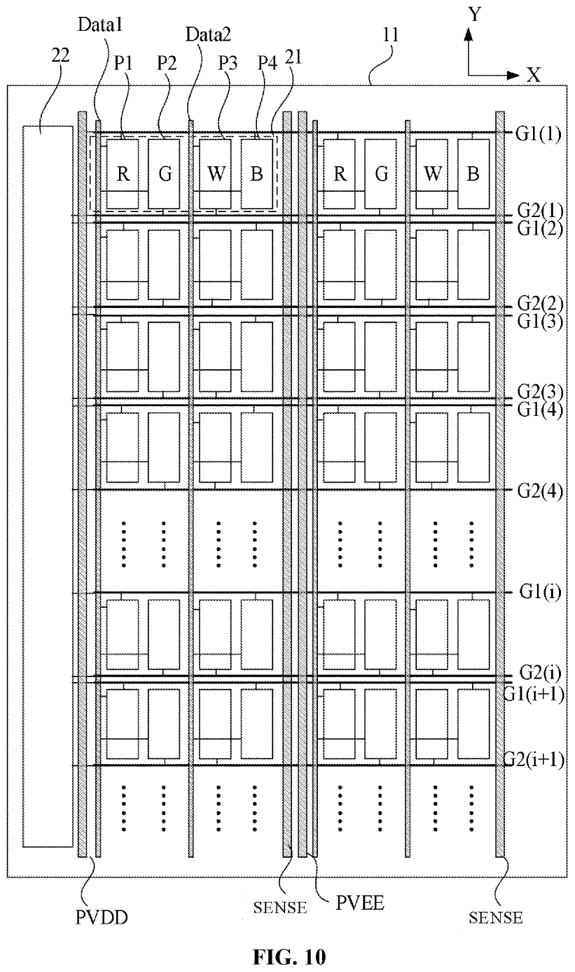

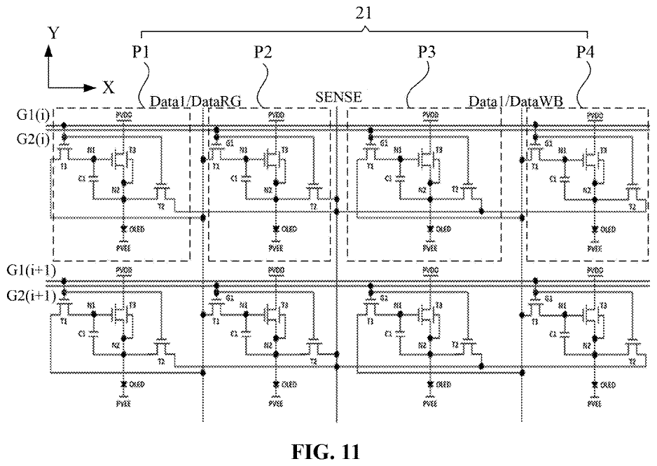

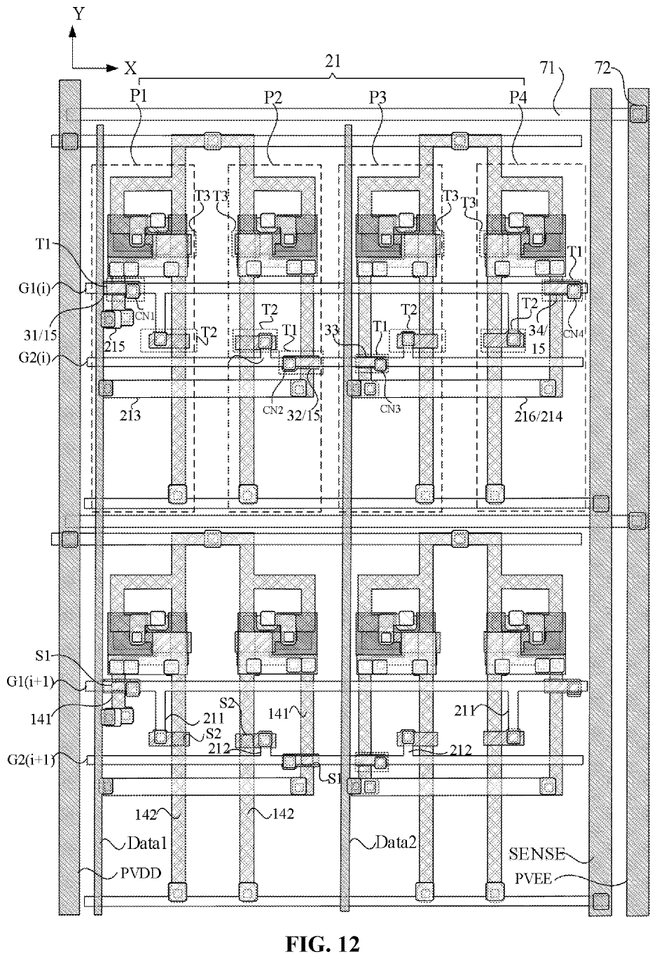

FIG. 10 is a diagram illustrating the structure of another display panel according to an embodiment of the present disclosure. FIG. 11 is a diagram illustrating the structure of another pixel driving circuit according to an embodiment of the present disclosure. FIG. 12 is a diagram illustrating a layout of another pixel driving circuit according to an embodiment of the present disclosure. In one or more embodiments, the first scan line G1 may be configured to provide the scan signal to the gate of the first transistor T1 of the first pixel driving circuit P1 and the gate of the first transistor T1 of the fourth pixel driving circuit P4, and the second scan line G2 may be configured to provide the scan signal to the gate of the first transistor T1 of the second pixel driving circuit P2 and the gate of the first transistor T1 of the third pixel driving circuit P3, where D1=D4, and D2=D3.

In the preceding embodiments, examples where the first pixel driving circuit P1 and the third pixel driving circuit P3 share a scan line, and the second pixel driving circuit P2 and the fourth pixel driving circuit P4 share a scan line are given for illustration. In this embodiment, it is also possible for the first pixel driving circuit P1 and the fourth pixel driving circuit P4 to share a scan line, and for the second pixel driving circuit P2 and the third pixel driving circuit P3 to share a scan line. For example, the first scan line G1 may also provide scan signals to the first pixel driving circuit P1 and the fourth pixel driving circuit P4, while the second scan line G2 provides scan signals to the second pixel driving circuit P2 and the third pixel driving circuit P3. In this embodiment, in the pixel unit 21 composed of the first pixel driving circuit P1, the second pixel driving circuit P2, the third pixel driving circuit P3, and the fourth pixel driving circuit P4, two pixel driving circuits connected to the same data line need to be connected to different scan lines to achieve time-division lighting of the two pixel driving circuits. This configuration halves the number of data lines while maintaining a high resolution of the display panel.

In one or more embodiments, D1=D4, and D2=D3. When D1=D4, the first transistor T1 of the first pixel driving circuit P1 and the first transistor T1 of the fourth pixel driving circuit P4, both connected to the first scan line G1, are disposed adjacent to the first scan line G1. This configuration facilitates the sharing of the first scan line G1 between the first pixel driving circuit P1 and the fourth pixel driving circuit P4 without the need to provide an additional scan line for the fourth pixel driving circuit P4, thereby simplifying the wiring arrangement of the pixel driving circuits. Similarly, when D2=D3, the first transistor T1 of the second pixel driving circuit P2 and the first transistor T1 of the third pixel driving circuit P3, both connected to the second scan line G2, are disposed adjacent to the second scan line G2. This facilitates the sharing of the second scan line G2 between the second pixel driving circuit P2 and the third pixel driving circuit P3 without the need to provide an additional scan line for the third pixel driving circuit P3, thereby simplifying the wiring arrangement of the pixel driving circuits.

In addition, when D1=D4 and D2=D3, the layout of the first transistor T1 and the drive transistor T3 of the first pixel driving circuit P1 may be the same as that of the fourth pixel driving circuit P4. The layout of the second pixel driving circuit P2 may be the same as that of the third pixel driving circuit P3. In this embodiment, the repeated layouts of the pixel driving circuits simplify the wiring arrangement of the pixel driving circuit layer and reduce the process complexity of the display panel. For example, the channel of the first transistor T1 of the first pixel driving circuit P1 may at least partially overlap with the first scan line G1, the channel of the first transistor T1 of the fourth pixel driving circuit P4 may at least partially overlap with the first scan line G1, the channel of the first transistor T1 of the second pixel driving circuit P2 may at least partially overlap with the second scan line G2, and the channel of the first transistor T1 of the third pixel driving circuit P3 may at least partially overlap with the second scan line G2, thereby avoiding the need to provide a larger gate for the first transistor T1 or the need to provide a longer connection line for the scan line along the second direction Y. This configuration reduces crossover arrangements in each pixel driving circuit and reduces the wiring complexity and manufacturing costs of the display panel.

With reference to FIG. 12, in one or more embodiments, in a direction perpendicular to the substrate 11, the projection of the first scan line G1 may at least partially overlap with the gate 31 of the first transistor T1 of the first pixel driving circuit P1, and the projection of the second scan line G2 may at least partially overlap with the gate 32 of the first transistor T1 of the second pixel driving circuit P2. In the direction perpendicular to the substrate 11, the projection of the first scan line G1 may at least partially overlap with the gate 34 of the first transistor T1 of the fourth pixel driving circuit P4, and the projection of the second scan line G2 may at least partially overlap with the gate 33 of the first transistor T1 of the third pixel driving circuit P3. In this embodiment, the gate layer 15 overlaps with a semiconductor to form the channels of the transistors, and the gate layer 15 is also electrically connected to corresponding scan lines to acquire scan signals. As shown in FIG. 12, in the direction perpendicular to the substrate, the overlapping portion between the gate 31 of the first transistor T1 of the first pixel driving circuit P1 and the semiconductor layer 14 forms the channel of the first transistor T1. The projection of the first scan line G1 may at least partially overlap with the gate 31 of the first transistor T1 of the first pixel driving circuit P1. This configuration facilitates a direct electrical connection of the first scan line G1 to the gate 31 of the first transistor T1 through a first via CN1 perpendicular to the substrate and avoids the need to provide an additional extension line on the first scan line G1 to connect to the gate 31. Similarly, the overlapping portion between the gate 32 of the first transistor T1 of the second pixel driving circuit P2 and the semiconductor layer 14 forms the channel of the first transistor T1. The projection of the second scan line G2 may at least partially overlap with the gate 32 of the first transistor T1 of the second pixel driving circuit P2. This configuration facilitates a direct electrical connection of the second scan line G2 to the gate 32 of the first transistor T1 through a second via CN2 perpendicular to the substrate avoids the need to provide an additional extension line on the second scan line G2 to connect to the gate 32. In addition, the projection of the second scan line G2 may at least partially overlap with the gate 33 of the first transistor T1 of the third pixel driving circuit P3, which facilitates a direct electrical connection of the second scan line G2 to the gate 33 of the first transistor T1 through a via CN3 perpendicular to the substrate. The projection of the first scan line G1 may at least partially overlap with the gate 34 of the first transistor T1 of the fourth pixel driving circuit P4, which facilitates a direct electrical connection of the first scan line G1 to the gate 34 of the first transistor T1 through a via CN4 perpendicular to the substrate. In this embodiment, the scan lines overlap with the gates of the transistors to which the scan lines are connected. In this manner, the reduction of the arrangement of extension lines on the scan line layer is facilitated, and the complexity of the layers is reduced, thereby reducing the process difficulty of the display panel.

With continued reference to FIG. 10 to FIG. 12, in one or more embodiments, the display panel may also include a shift register circuit 22. Multiple pixel units 21 are arranged along the first direction X to form a pixel driving circuit row. The shift register circuit 22 is electrically connected to the pixel driving circuit row in a one-to-one correspondence and is configured to output the scan signal. In each pixel driving circuit row, the first scan line G1 is configured to provide the scan signal to the gate of the first transistor T1 of the first pixel driving circuit P1 and the gate of the first transistor T1 of the fourth pixel driving circuit P4, and the second scan line G2 is configured to provide the scan signal to the gate of the first transistor of the second pixel driving circuit P2 and the gate of the first transistor of the third pixel driving circuit P3.

The shift register circuit 22 may include cascaded first shift register units that provide scan signals to the first scan line G1, and cascaded second shift register units that provide scan signals to the second scan line G2. The first shift register units may be in a one-to-one correspondence with the pixel driving circuit rows, thereby providing scan signals to the first scan line G1 of a corresponding pixel driving circuit row. The second shift register units may be in a one-to-one correspondence with the pixel driving circuit rows, thereby providing scan signals to the second scan line G2 of a corresponding pixel driving circuit row. As shown in FIG. 12, in each row of pixel driving circuits from the first row of pixel driving circuit to the M-th row of pixel driving circuit, the first scan line G1 outputs the scan signal from a corresponding first shift register unit to the first pixel driving circuit P1 and the fourth pixel driving circuit P4, and the second scan line G2 outputs the scan signal from a corresponding second shift register unit to the second pixel driving circuit P2 and the third pixel driving circuit P3. As shown in FIG. 12, the scanning order of the scan lines corresponding to each row of pixel driving circuits is sequentially the first scan line G1 followed by the second scan line G2. The display panel in this embodiment can achieve the row-by-row DGLD driving of the pixel driving circuits. The first data line Data1 and the second data line Data2 provide data signals to different pixel driving circuits in a time-division manner, thereby halving the number of the first data lines Data1 and the second data lines Data2 in the entire display panel, reducing the number of driver chips, and lowering the manufacturing costs of the display panel, especially the manufacturing costs of OLED TV display panels.

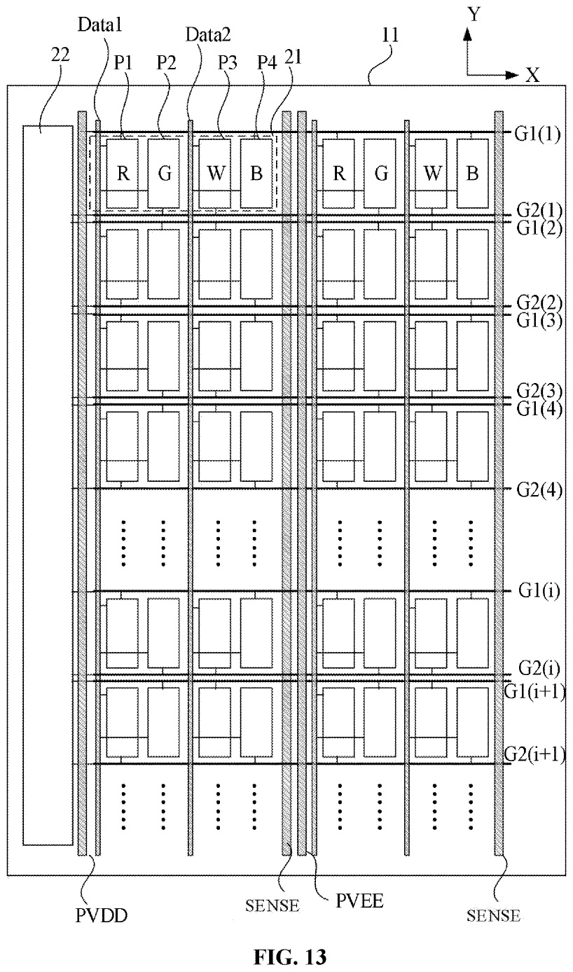

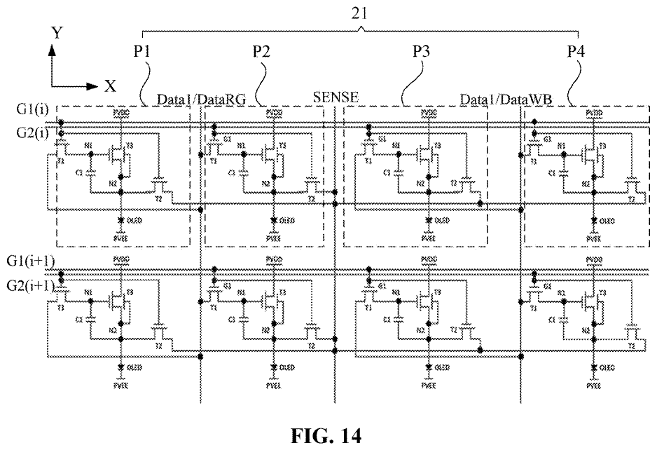

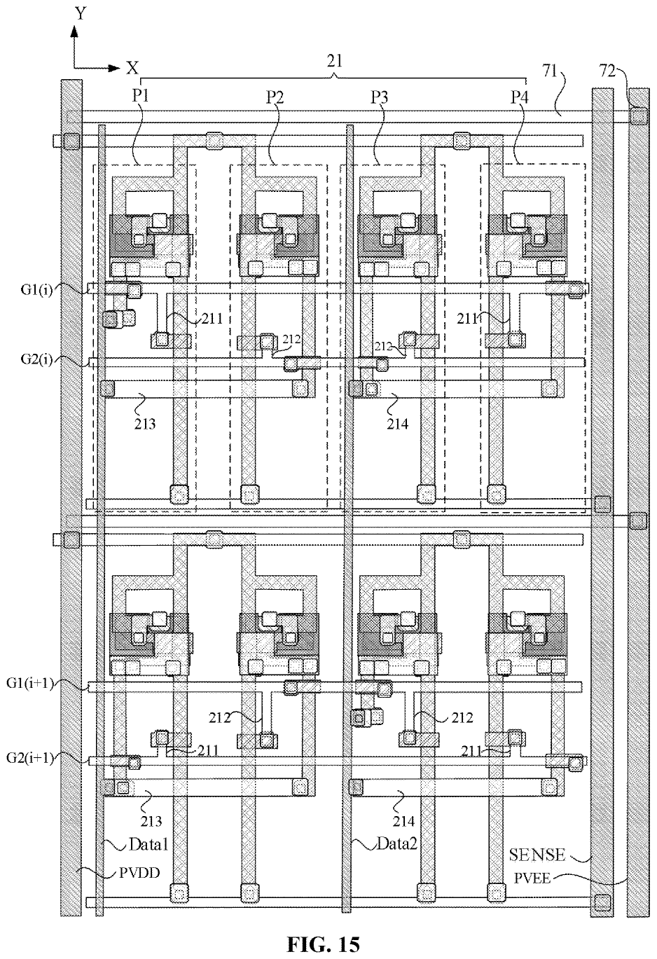

FIG. 13 is a diagram illustrating the structure of another display panel according to an embodiment of the present disclosure. FIG. 14 is a diagram illustrating the structure of another pixel driving circuit according to an embodiment of the present disclosure. FIG. 15 is a diagram illustrating a layout of another pixel driving circuit according to an embodiment of the present disclosure. In one or more embodiments, the display panel may also include a shift register circuit 22. Multiple pixel units 21 are arranged along the first direction X to form pixel driving circuit rows. The shift register circuit 22 is electrically connected to the pixel driving circuit rows in a one-to-one correspondence and is configured to output the scan signal. In an i-th pixel driving circuit row, the first scan line G1(i) is configured to provide the scan signal to the gate of the first transistor T1 of the first pixel driving circuit P1 and the gate of the first transistor T1 of the fourth pixel driving circuit P4, and the second scan line G2(i) is configured to provide the scan signal to the gate of the first transistor T1 of the second pixel driving circuit P2 and the gate of the first transistor T1 of the third pixel driving circuit P3. In an (i+1)-th pixel driving circuit row, the first scan line G1(i+1) is configured to provide the scan signal to the gate of the first transistor T1 of the second pixel driving circuit P2 and the gate of the first transistor T1 of the third pixel driving circuit P3, and the second scan line G2(i+1) is configured to provide the scan signal to the gate of the first transistor T1 of the first pixel driving circuit P1 and the gate of the first transistor T4 of the fourth pixel driving circuit P3. Here, i is an integer, 1≤i≤M−1, and M is the total number of pixel driving circuit rows.

FIG. 10 is compared with FIG. 13, both of which show display panels in which the first pixel driving circuit P1 and the fourth pixel driving circuit P4 share one scan line, and the second pixel driving circuit P2 and the third pixel driving circuit P3 share one scan line. The difference lies in the following: In the solution of FIG. 10, the first scan line G1(i) of the i-th pixel driving circuit row is used to provide scan signals to the first pixel driving circuit P1 and the fourth pixel driving circuit P4, and the first scan line G1(i+1) of the (i+1)-th pixel driving circuit row is also used to provide scan signals to the first pixel driving circuit P1 and the fourth pixel driving circuit P4. In contrast, in the solution shown in FIG. 13, in the i-th pixel driving circuit row, the first scan line G1(i) is used to provide scan signals to the first pixel driving circuit P1 and the fourth pixel driving circuit P4, and the second scan line G2(i) is used to provide scan signals to the second pixel driving circuit P2 and the third pixel driving circuit P3. In the (i+1)-th pixel driving circuit row, the first scan line G1(i+1) is used to provide scan signals to the second pixel driving circuit P2 and the third pixel driving circuit P3, and the second scan line G2(i+1) is used to provide scan signals to the first pixel driving circuit P1 and the fourth pixel driving circuit P4. Therefore, in this embodiment, two adjacent rows of pixel driving circuits are used as a unit. In the i-th pixel driving circuit row, the first scan line G1(i) is used to provide scan signals to the first pixel driving circuit P1 and the fourth pixel driving circuit P4. In the (i+1)-th pixel driving circuit row, the first scan line G1(i+1) is used to provide scan signals to the second pixel driving circuit P2 and the third pixel driving circuit P3. Consequently, in two adjacent rows of pixel driving circuits, the first pixel driving circuit P1, the third pixel driving circuit P3, the second pixel driving circuit P2, and the fourth pixel driving circuit P4 are all effectively driven by the first scan line G1. The first scan line G1(i) and the first scan line G1(i+1) are generated by cascading the same shift register, resulting in small differences in the provided scan signals. This configuration effectively reduces issues such as mura and improves the display effect of the display panel. Similarly, the second scan line G2(i) and the second scan line G2(i+1) are generated by cascading the same shift register, resulting in a small difference in the provided scan signals. Likewise, two adjacent rows of pixel driving circuits may be used as a unit to effectively drive the first pixel driving circuit P1, the third pixel driving circuit P3, the second pixel driving circuit P2, and the fourth pixel driving circuit P4 using the second scan line G2, thereby preventing display non-uniformity.

With reference to FIG. 13 to FIG. 15, it should be noted that along the second direction Y, the arrangement order of the scan lines in each pixel driving circuit row is the first scan line G1 followed by the second scan line G2. In this embodiment, two adjacent rows of pixel driving circuits are used as a unit. The first pixel driving circuit P1 and the fourth pixel driving circuit P4, as well as the second pixel driving circuit P2 and the third pixel driving circuit P3, are all driven by either the first scan line or the second scan line. The difference between two first scan lines is relatively small, and the difference between two second scan lines is relatively small, resulting in no significant difference in the scan signals. This embodiment effectively avoids display errors caused by the situation where the first pixel driving circuit P1, the third pixel driving circuit P3, the second pixel driving circuit P2, and the fourth pixel driving circuit P4 are driven by different scan lines, thereby preventing display non-uniformity.

With continued reference to FIG. 3, in one or more embodiments, the pixel driving circuit may also include a storage capacitor C1, a second transistor T2, and a light-emitting element 210. A first electrode of the first transistor T1 receives a data signal, and a second electrode of the first transistor T1 is electrically connected to a gate of the drive transistor T3. A first electrode of the drive transistor T3 receives a first power signal, and a second electrode of the drive transistor T3 is electrically connected to a first electrode of the second transistor T2. A second electrode of the second transistor T2 is configured to output a sensing signal. A first plate of the storage capacitor C1 is electrically connected to the gate of the drive transistor T3, and a second plate of the storage capacitor C1 is electrically connected to the second electrode of the drive transistor T3. A gate of the second transistor T2 is electrically connected to the gate of the first transistor T1. The second electrode of the drive transistor T3 is configured to connect to a first terminal of the light-emitting element 210, and a second terminal of the light-emitting element 210 receives a second power signal.

A 3T1C (that is, three transistors and one capacitor) pixel driving circuit is used as an example for illustration. Each pixel driving circuit includes a storage capacitor C1, a second transistor T2, and a light-emitting element 210. The first electrode of the first transistor T1 is connected to the data line, the second electrode of the first transistor T1 is connected to the gate of the drive transistor T3, and the control terminal of the first transistor T1 receives a scan signal. The first transistor T1 is used to transmit the data signal to the gate of the drive transistor T3 when the scan signal is an active pulse. The first electrode of the drive transistor T3 is connected to the first power signal line. The second electrode of the drive transistor T3 is connected to the first terminal of the light-emitting element 210. The second terminal of the light-emitting element 210 receives the second power signal. In one or more embodiments, the potential of the first power signal is higher than that of the second power signal. The first electrode of the second transistor T2 is connected to the second electrode of the drive transistor T3. The second electrode of the second transistor T2 is used to receive a reference voltage or output a sensing signal. The gate of the drive transistor T3 may serve as a first node N1, and the second electrode of the drive transistor T3 may serve as a second node N2. The first plate of the storage capacitor C1 is connected to the first node N1, and the second plate of the storage capacitor C1 is connected to the second node N2. The operation process of the pixel driving circuit is as follows: In an initialization phase, the first transistor T1 is turned on in response to an active pulse of the scan signal and applies the data signal input from the data line to the first node N1. The data signal is the voltage corresponding to the image data input to the pixel driving circuit in the current display frame. The second transistor T2 is turned on in response to an active pulse of the scan signal and inputs a reference voltage to the second node N2 to initialize the second node N2, thereby turning on the drive transistor T3. In a light emission phase, the scan signal controls the first transistor T1 and the second transistor T2 to be turned off. The potential at the first terminal of the light-emitting element 210 rises, and the light-emitting element 210 emits light. In a sensing phase, the scan signal controls the first transistor T1 and the second transistor T2 to be turned on. The data signal is turned off, the drive transistor T3 is turned off, and the second electrode of the second transistor T2 outputs a sensing current.

The above transistors may be P-type transistors or N-type transistors, which are not specifically limited in this embodiment. The embodiments of the present disclosure are described using N-type transistors as an example. It should be noted that in this embodiment, the gate of the second transistor T2 and the gate of the first transistor T1 are connected to the same scan line, and it is not required to provide an additional scan line for the gate of the second transistor T2. Therefore, in this embodiment, each pixel driving circuit is connected to one scan line, and each pixel unit 21 is correspondingly provided with two scan lines instead of four. The gates of the first transistor T1 and the second transistor T2 receive the same signal, which halves the number of scan lines for the display panel, simplifies the wiring arrangement, reduces the number of shift register circuits, and lowers wiring complexity. In addition, in this embodiment, the gate of the second transistor T2 and the gate of the first transistor T1 may also be connected to different scan lines, thereby enabling the first transistor T1 and the second transistor T2 to be individually controlled to be turned on or off and thus allowing for more compensation functions and sensing functions in each pixel driving circuit.

With continued reference to FIG. 4, in one or more embodiments, along the second direction Y, the gate of the second transistor T2 may be disposed between the first scan line G1 and the second scan line G2. In this embodiment, two pixel driving circuits connected to the same data line need to be connected to different scan lines. For example, the first pixel driving circuit P1 is connected to the first scan line G1, and the second pixel driving circuit P2 is connected to the second scan line G2. The first scan line G1 and the second scan line G2, which are disposed in the same layer, are arranged along the second direction Y. Therefore, the gate of the second transistor T2 may be disposed between the first scan line G1 and the second scan line G2. The first scan line G1 may be connected to the gate of the second transistor T2 of the first pixel driving circuit P1 through a relatively short extension line along the second direction Y. The second scan line G2 may also be connected to the gate of the second transistor T2 of the second pixel driving circuit P2 through a relatively short extension line along the second direction Y. This embodiment can simplify the wiring arrangement of the metal layer where the scan lines are located and reduce the process complexity of the pixel driving circuits.

With continued reference to FIG. 4, in one or more embodiments, the first scan line G1 provides the scan signal to the first pixel driving circuit P1, and the second scan line G2 provides the scan signal to the second pixel driving circuit P2. The display panel may also include a first auxiliary connection line 211 and a second auxiliary connection line 212 extending along the second direction Y. The first auxiliary connection line 211 is configured to connect the gate of the second transistor T2 of the first pixel driving circuit P1 to the first scan line G1. The second auxiliary connection line 212 is configured to connect the gate of the second transistor T2 of the second pixel driving circuit P2 to the second scan line G2. In this embodiment, the first pixel driving circuit P1 is connected to the first scan line G1, and the second pixel driving circuit P2 is connected to the second scan line G2. The gate of the second transistor T2 is disposed between the first scan line G1 and the second scan line G2. The gate of the first transistor T1 of the first pixel driving circuit P1 overlaps with the first scan line G1. Therefore, the first scan line G1 is connected to the gate of the first transistor T1 of the first pixel driving circuit P1 through a first via CN1, and the first scan line G1 is connected to the gate of the second transistor T2 of the first pixel driving circuit P1 through the first auxiliary connection line 211. The gate of the first transistor T1 of the second pixel driving circuit P2 overlaps with the second scan line G2. Therefore, the second scan line G2 is connected to the gate of the first transistor T1 of the second pixel driving circuit P2 through a second via CN2, and the second scan line G2 is connected to the gate of the second transistor T2 of the second pixel driving circuit P2 through the second auxiliary connection line 212. In this embodiment, the gate of the second transistor T2 is disposed between the first scan line G1 and the second scan line G2 so that the arrangement of extension lines on the scan line layer is effectively reduced, the complexity of the layers is lowered, and the process difficulty of the display panel is thereby reduced.

With continued reference to FIG. 4, in one or more embodiments, if the first scan line G1 is connected to the third pixel driving circuit P3 and the second scan line G2 is connected to the fourth pixel driving circuit P4, the display panel may also include a first auxiliary connection line 211 that connects the gate of the second transistor T2 of the third pixel driving circuit P3 to the first scan line G1, and a second auxiliary connection line 212 that connects the gate of the second transistor T2 of the fourth pixel driving circuit P4 to the second scan line G2.

With reference to FIG. 12, in one or more embodiments, if the first scan line G1 is connected to the fourth pixel driving circuit P4 and the second scan line G2 is connected to the third pixel driving circuit P3, the display panel may also include a first auxiliary connection line 211 that connects the gate of the second transistor T2 of the fourth pixel driving circuit P4 to the first scan line G1, and a second auxiliary connection line 212 that connects the gate of the second transistor T2 of the third pixel driving circuit P3 to the second scan line G2.

As shown in FIG. 3 and FIG. 4, in one or more embodiments, the display panel may also include a reference voltage line SENSE extending along the second direction Y. The reference voltage line SENSE is electrically connected to a second electrode of a second transistor T2. At least two pixel units 21 are connected to the same reference voltage line SENSE. The reference voltage line SENSE is electrically connected to the second electrode of the second transistor T2 to provide a reference voltage signal to the pixel driving circuits and to collect sensing signals, thereby acquiring characteristic values such as the threshold voltage or mobility of the drive transistor T3 and thus sensing the performance of the drive transistor T3. Along the first direction X, multiple pixel driving circuits may share the reference voltage line SENSE. As shown in FIG. 3, this embodiment uses an example in which each pixel unit 21 is provided with one reference voltage line SENSE for illustration. In addition, at least two pixel units 21 may be configured to be connected to the same reference voltage line SENSE in this embodiment, thereby further reducing the number of reference voltage lines SENSE, reducing wiring complexity of the pixel driving circuits, and lowering manufacturing costs of the panel.

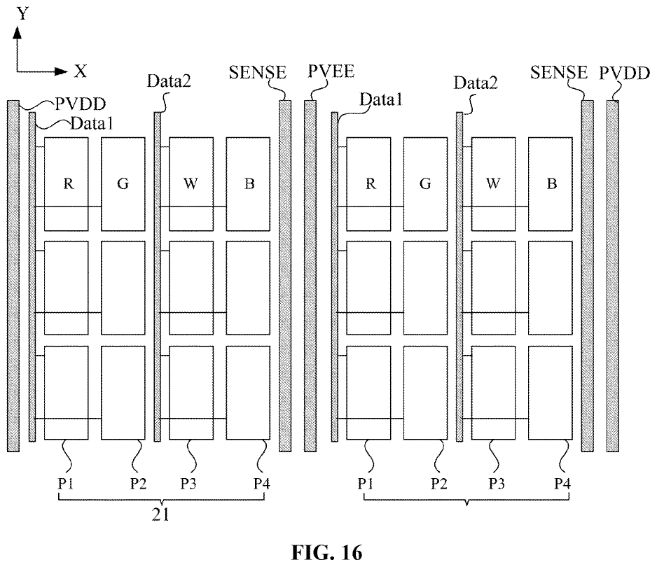

FIG. 16 is a diagram illustrating a partial structure of a display panel according to an embodiment of the present disclosure. In one or more embodiments, the display panel may also include a first power signal line PVDD and a second power signal line PVEE extending along the second direction Y. The first power signal line PVDD is configured to provide a first power signal to the pixel driving circuit. The second power signal line PVEE is configured to provide a second power signal to the pixel driving circuit. Along the first direction X, the reference voltage line SENSE and the first power signal line PVDD are disposed between adjacent pixel units 21, or the reference voltage line SENSE and the second power signal line PVEE are disposed between adjacent pixel units 21. In this embodiment, a first power signal line PVDD and a second power signal line PVEE are disposed parallel to the reference voltage line SENSE. The first power signal line PVDD is used to output a first power signal, and the second power signal line PVEE is used to output a second power signal. Along the first direction X, the reference voltage line SENSE and the first power signal line PVDD are disposed between adjacent pixel units 21, or the reference voltage line SENSE and the second power signal line PVEE are disposed between adjacent pixel units 21. For example, along the first direction X, if the reference voltage line SENSE and the first power signal line PVDD are disposed between a first pixel unit 21 and a second pixel unit 21, the reference voltage line SENSE and the second power signal line PVEE are disposed between the second pixel unit 21 and a third pixel unit 21. In this embodiment, the first power signal line PVDD and the second power signal line PVEE are not required to be disposed between every pair of adjacent pixel units 21, thereby reducing the number of the first power signal lines PVDD and the second power signal lines PVEE, lowering wiring density of the display panel, and reducing process difficulty and manufacturing costs of the display panel. In one or more embodiments, in this embodiment, the first power signal line PVDD, the second power signal line PVEE, and the reference voltage line SENSE need to provide corresponding potential signals to the pixel driving circuits across the entire display panel. Therefore, the wiring widths of the first power signal line PVDD, the second power signal line PVEE, and the reference voltage line SENSE are greater than that of the first data line Data1 and the second data line Data2.

With continued reference to FIG. 3 and FIG. 4, in one or more embodiments, along the first direction X, the first data line Data1 may be disposed on a side of the first pixel driving circuit P1 facing away from the second pixel driving circuit P2, and the second data line Data2 may be disposed on a side of the third pixel driving circuit P3 facing away from the fourth pixel driving circuit P4. The display panel also includes a third auxiliary connection line 213 and a fourth auxiliary connection line 214 extending along the first direction X. The third auxiliary connection line 213 connects the first data line Data 1 to a first electrode of the first transistor T1 of the second pixel driving circuit P2. The fourth auxiliary connection line 214 connects the second data line Data2 to a first electrode of the first transistor T1 of the fourth pixel driving circuit P4.

In this embodiment, the first data line Data1 may be disposed on one side of the overall structure formed by the first pixel driving circuit P1 and the second pixel driving circuit P2. For example, when the first data line Data1 is disposed adjacent to the first pixel driving circuit P1 and the first electrode of the first transistor T1 of the second pixel driving circuit P2 needs to be electrically connected to the first data line Data1, the first electrode of the first transistor T1 of the second pixel driving circuit P2 needs to be electrically connected to the first data line Data1 by crossing over the first pixel driving circuit P1 through the third auxiliary connection line 213 extending along the first direction X. Similarly, the second data line Data2 may be disposed on one side of the overall structure formed by the third pixel driving circuit P3 and the fourth pixel driving circuit P4 and disposed adjacent to the third pixel driving circuit P3. The first electrode of the first transistor T1 of the fourth pixel driving circuit P4 is connected to the second data line Data2 by crossing over the third pixel driving circuit P3 through the fourth auxiliary connection line 214. As shown in FIG. 4, in the direction perpendicular to the substrate, the projection of the third auxiliary connection line 213 has no overlap with any transistor or capacitor, and the projection of the fourth auxiliary connection line 214 has no overlap with any transistor or capacitor. This configuration avoids the need to provide additional crossover lines, reduces wiring complexity, prevents the third auxiliary connection line 213 from affecting signals of other devices, improves the accuracy of the drive current output from the pixel driving circuit to the light-emitting element, and enhances the image display quality of the display panel.

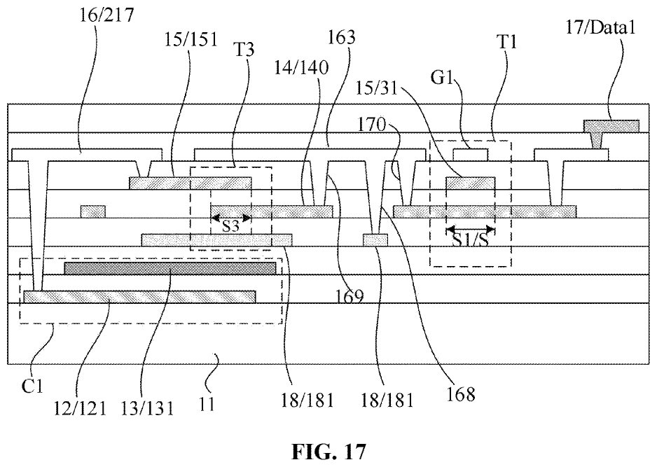

FIG. 17 is a sectional view of the display panel in FIG. 4 taken along line segment a-a′. With reference to FIG. 4 and FIG. 17, in one or more embodiments, the display panel may include a first metal layer 12, a second metal layer 13, a semiconductor layer 14, a gate layer 15, a third metal layer 16, and a fourth metal layer 17 sequentially disposed on the substrate 11. The first metal layer 12 is provided with the first plate 121 of the storage capacitor C1. The second metal layer 13 is provided with the second plate 131 of the storage capacitor C1. The semiconductor layer 14 is provided with the active layers of transistors of the pixel driving circuit. The gate layer 15 is provided with gates of the transistors of the pixel driving circuit. The third metal layer 16 is provided with the first scan line G1 and the second scan line G2. The fourth metal layer 17 is provided with a first power signal line PVDD, a second power signal line PVEE, a reference voltage line SENSE, the first data line Data1, and the second data line Data2. In this embodiment, the gates of the transistors and the scan lines are disposed in different metal layers. For example, the first metal layer 12 and the second metal layer 13 are sequentially disposed on the substrate 11. The first metal layer 12 is provided with the first plate 121 of the storage capacitor C1, and the second metal layer 13 is provided with the second plate 131 of the storage capacitor C1. The semiconductor layer 14 is disposed on a side of the second metal layer 13 facing away from the substrate 11. The gate layer 15 and the third metal layer 16 are sequentially disposed on a side of the semiconductor layer 14 facing away from the substrate 11. The gate layer 15 is provided with the gates of the transistors. In the direction perpendicular to the substrate 11, the overlapping portions between the active layer and the gates form channels S. For example, the overlapping portion between the active layer and the gate 31 of the first transistor T1 forms a first channel S1 of the first transistor T1. The third metal layer 16 is provided with the first scan line G1 and the second scan line G2. The first scan line G1 is electrically connected to the gate 31 of the first transistor T1 through the first via CN1 to output the scan signal to the gate 31 of the first transistor T1. The fourth metal layer 17 is disposed on a side of the third metal layer 16 facing away from the substrate 11 and is used to provide the first power signal line PVDD, the second power signal line PVEE, the reference voltage line SENSE, the first data line Data1, and the second data line Data2. In this embodiment, to enable each transistor to acquire a channel layer with good transmission performance, the gate layer 15 is disposed between the semiconductor layer 14 and the third metal layer 16 where the scan lines are located. This configuration allows the overlapping portions between the active layer and the gates to form channels. Since the gate layer 15 is relatively close to the semiconductor layer 14, the formation of channels for each transistor is facilitated, and a quick adjustment of the on and off states of the channels through the gate layer 15 is enabled. In addition, it is not required to provide various extension lines in the third metal layer 16 to overlap with the semiconductor layer 14. Only vias are required to connect to the gate layer 15, which helps simplify the wiring complexity of the first scan line G1 and the second scan line G2.

With continued reference to FIG. 4, in one or more embodiments, the first scan line G1 provides the scan signal to the first pixel driving circuit P1, and the second scan line G2 provides the scan signal to the second pixel driving circuit P2. In a direction perpendicular to the substrate 11, the first scan line G1 may be electrically connected to the gate 31 of the first transistor T1 of the first pixel driving circuit P1 through a first via CN1, and the second scan line G2 may be electrically connected to the gate 32 of the first transistor T1 of the second pixel driving circuit P2 through a second via CN2. The third metal layer 16 also includes the first auxiliary connection line 211 and the second auxiliary connection line 212 extending along the second direction Y. The first scan line G1 is electrically connected to the gate 311 of the second transistor T2 of the first pixel driving circuit P1 through the first auxiliary connection line 211. The second scan line G2 is electrically connected to the gate 321 of the second transistor T2 of the second pixel driving circuit P2 through the second auxiliary connection line 212. In this embodiment, the gate 31 of the first transistor T1 at least partially overlaps with the first scan line G1, thereby enabling the first scan line G1 to be directly electrically connected to the gate 31 of the first transistor T1 through the first via CN1 perpendicular to the substrate 11 and thus enabling the first scan line G1 to provide the scan signal to the gate 31 of the first transistor T1. This configuration reduces crossover arrangements on the first scan line G1, lowers wiring complexity in the metal layers, increases the degree of integration of each pixel driving circuit, reduces the occupied area of the pixel driving circuits in the plane parallel to the substrate, and facilitates the achievement of a display panel with a higher resolution. Similarly, the gate 32 of the first transistor T1 of the second pixel driving circuit P2 at least partially overlaps with the second scan line G2, thereby enabling the second scan line G2 to be directly electrically connected to the gate 32 of the first transistor T1 through the second via CN2 perpendicular to the substrate 11 to reduce crossover arrangements on the second scan line G2. Furthermore, the second transistors T2 of the first pixel driving circuit P1 and the second pixel driving circuit P2 are both disposed between the first scan line G1 and the second scan line G2. This configuration enables the first scan line G1 to be connected to the gate 311 of the second transistor T2 of the first pixel driving circuit P1 through the relatively short first auxiliary connection line 211, and enables the second scan line G 2 to be connected to the gate 321 of the second transistor T2 of the second pixel driving circuit P2 through the relatively short second auxiliary connection line 212. In this embodiment, the arrangement of extension lines on the first scan line G1 and the second scan line G2 is further reduced, and the complexity of the metal layer where the scan lines are located is lowered. Moreover, the second transistor T2 of each pixel driving circuit is disposed between the first scan line G1 and the second scan line G2. In this manner, the degree of integration of the pixel driving circuits is further improved, the occupied area of the pixel driving circuits in the plane parallel to the substrate is reduced, and the achievement of a display panel with a higher resolution is facilitated.

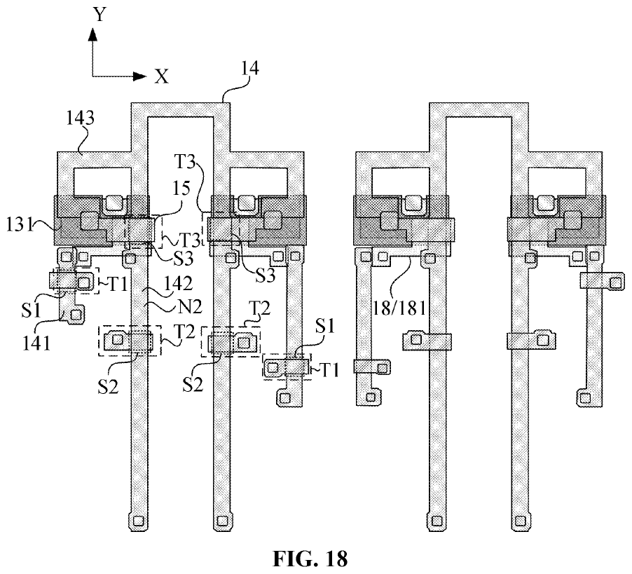

FIG. 18 is a diagram illustrating a layout of another pixel driving circuit according to an embodiment of the present disclosure. To clearly illustrate the specific structure of the semiconductor layer 14, FIG. 18 does not show the third metal layer 16 and the fourth metal layer 17. As shown in FIG. 17 and FIG. 18, in one or more embodiments, the semiconductor layer 14 of each pixel driving circuit may include a first connection branch 141 and a second connection branch 142 extending along the second direction Y. In a direction perpendicular to the substrate 11, the overlapping region between the first connection branch 141 and the gate of the first transistor T1 is the channel S1 of the first transistor T1. In the direction perpendicular to the substrate 11, the overlapping region between the second connection branch 142 and the gate of the drive transistor T3 is the channel S3 of the drive transistor T3. The overlapping region between the second connection branch 142 and the gate of the second transistor T2 is the channel S2 of the second transistor T2. A first terminal of the second connection branch 142 receives the first power signal. A second terminal of the second connection branch 142 is configured to be connected to the reference voltage line SENSE. The second connection branch 142 forms a second node N2 between the channel S3 of the drive transistor T3 and the channel S2 of the second transistor T2.

In this embodiment, the semiconductor layer 14 includes a first connection branch 141 and a second connection branch 142 extending along the second direction Y. The first connection branch 141 and the second connection branch 142 are disconnected. The overlapping region between the first connection branch 141 and the gate of the first transistor T1 is the channel S1 of the first transistor T1. The overlapping region between the second connection branch 142 and the gate of the drive transistor T3 is the channel S3 of the drive transistor T3. The overlapping region between the second connection branch 142 and the gate of the second transistor T2 is the channel S2 of the second transistor T2. In this embodiment, the second connection branch 142 also serves as the connection line between the second transistor T2 and the drive transistor T3, as the connection line between the drive transistor T3 and the first power signal, and as the connection line between the second transistor T2 and the reference voltage. In this embodiment, the entire circuit path for the first power signal, the drive transistor T3, the second transistor T2, and the reference voltage is achieved by means of the second connection branch 142 that runs through the pixel driving circuit. In this manner, no additional crossover lines are required to perform the above connection functions, and the wiring structure is simple, thereby reducing wiring complexity and manufacturing costs of the display panel.

It should be noted that as shown in FIG. 18, the second connection branch 142 is also provided with an extension portion 143. The extension portion 143 extends between the second plate 131 of the capacitor C1 and the third metal layer 16 to prevent signal interference between the second plate 131 and the third metal layer 16, thereby improving the display accuracy of the light-emitting element driven by the pixel driving circuit and enhancing the display effect of the display panel.

In one or more embodiments, the first scan line G1 provides the scan signal to the first pixel driving circuit P1, and the second scan line G2 provides the scan signal to the second pixel driving circuit P2. In the direction perpendicular to the substrate 11, the first connection branch 141 of the first pixel driving circuit P1 intersects with the first scan line G1. In the direction perpendicular to the substrate 11, the first connection branch 141 of the second pixel driving circuit P2 intersects with both the second scan line G2 and the first scan line G1.

With reference to FIG. 5 and FIG. 10, in each pixel driving circuit row, the first pixel driving circuit P1 is connected to the first scan line G1, and the second pixel driving circuit P2 is connected to the second scan line G2. As shown in FIG. 6 and FIG. 12, the first connection branch 141 of the first pixel driving circuit P1 needs to form the channel S1 of the first transistor T1, so the first connection branch 141 only needs to overlap with the first scan line G1. The first connection branch 141 of the second pixel driving circuit P2 needs to form the channel S1 of the first transistor T1, so the first connection branch 141 needs to overlap with the second scan line G2. Therefore, the first connection branch 141 of the second pixel driving circuit P2 needs to intersect with both the first scan line G1 and the second scan line G2. In this embodiment, the first connection branch 141 of the first pixel driving circuit P1 may be made relatively short to save the wiring in the semiconductor layer 14, reduce the planar area occupied by the semiconductor layer 14, and improve the degree of integration of the pixel driving circuit.

In one or more embodiments, the first scan line G1 provides the scan signal to the first pixel driving circuit P1, and the second scan line G2 provides the scan signal to the second pixel driving circuit P2. The first scan line G1 provides the scan signal to the third pixel driving circuit P3, and the second scan line G2 provides the scan signal to the fourth pixel driving circuit P4. The third metal layer 16 may also include a third auxiliary connection line 213, a fourth auxiliary connection line 214, a fifth auxiliary connection line 215, and a sixth auxiliary connection line 216 extending along the first direction X. The fifth auxiliary connection line 215 is configured to connect the first data line Data1 to a second terminal of the first connection branch 141 of the first pixel driving circuit P1. The third auxiliary connection line 213 is configured to connect the first data line Data1 to a second terminal of the first connection branch 141 of the second pixel driving circuit P2. The sixth auxiliary connection line 216 is configured to connect the second data line Data2 to a second terminal of the first connection branch 141 of the third pixel driving circuit P3. The fourth auxiliary connection line 214 is configured to connect the second data line Data2 to a second terminal of the first connection branch 141 in the fourth pixel driving circuit P4. As shown in FIG. 6, in this embodiment, the second terminal of the first connection branch 141 of the first pixel driving circuit P1 is connected to the first data line Data1 through the fifth auxiliary connection line 215. The second terminal of the first connection branch 141 of the third pixel driving circuit P3 is connected to the second data line Data2 through the sixth auxiliary connection line 216. The second terminal of the first connection branch 141 of the second pixel driving circuit P2 is connected to the first data line Data 1 through the third auxiliary connection line 213. The second terminal of the first connection branch 141 of the fourth pixel driving circuit P4 is connected to the second data line Data 2 through the fourth auxiliary connection line 214. In this embodiment, the first connection branches 141 of the first pixel driving circuit P1 and the third pixel driving circuit P3 may be made relatively short, and the first pixel driving circuit P1 and the third pixel driving circuit P3 are connected to corresponding data lines through their respective connection branches. This configuration saves the wiring in the semiconductor layer 14, reduces the planar area occupied by the semiconductor layer 14, and improves the degree of integration of the pixel driving circuit.

With reference to FIG. 12, it should be noted that when the first pixel driving circuit P1 and the fourth pixel driving circuit P4 are connected to the first scan line G1, and the second pixel driving circuit P2 and the third pixel driving circuit P3 are connected to the second scan line G2, the fourth auxiliary connection line 214 and the sixth auxiliary connection line 216 may be the same auxiliary connection line, thereby further reducing the number of auxiliary connection lines, lowering wiring complexity in the third metal layer 16, and improving the degree of integration of the pixel driving circuit.

In one or more embodiments, the first scan line G1 provides the scan signal to the second pixel driving circuit P2, and the second scan line G2 provides the scan signal to the first pixel driving circuit P1. In the direction perpendicular to the substrate 11, the first connection branch 141 of the first pixel driving circuit P1 intersects with both the first scan line G1 and the second scan line G2. In the direction perpendicular to the substrate 11, the first connection branch 141 of the second pixel driving circuit P2 intersects with both the second scan line G2 and the first scan line G1. With reference to FIG. 7 and FIG. 13, if the first scan line G1(i) connected to an i-th pixel driving circuit row provides the scan signal to the first pixel driving circuit P1 and the second scan line G2(i) provides the scan signal to the second pixel driving circuit P2, the first scan line G1(i+1) connected to an (i+1)-th pixel driving circuit row provides the scan signal to the second pixel driving circuit P2 and the second scan line G2(i+1) provides the scan signal to the first pixel driving circuit P1. As shown in FIG. 9 and FIG. 15, the first connection branch 141 of the first pixel driving circuit P1 needs to form the channel of the first transistor T1, so the first connection branch 141 of the first pixel driving circuit P1 needs to intersect with both the second scan line G2 and the first scan line G1. The first connection branch 141 of the second pixel driving circuit P2 needs to form the channel of the first transistor T1, so the first connection branch 141 of the second pixel driving circuit P2 needs to intersect with the second scan line G2. However, to avoid crossover arrangements, the first connection branch 141 of the second pixel driving circuit P2 also needs to intersect with both the second scan line G2 and the first scan line G1. For the i-th pixel driving circuit row, the second terminal of the first connection branch 141 of the first pixel driving circuit P1 may be connected to the first data line Data1 through the fifth auxiliary connection line 215, and the second terminal of the first connection branch 141 of the third pixel driving circuit P3 may be connected to the second data line Data2 through the sixth auxiliary connection line 216, thereby shortening the first connection branches 141 of the first pixel driving circuit P1 and the third pixel driving circuit P3. In this embodiment, the first pixel driving circuit P1 and the second pixel driving circuit P2 may share one auxiliary connection line to achieve the connection to the first data line Data1, thereby simplifying the arrangement of auxiliary connection lines and improving the degree of integration of the pixel driving circuit.

As shown in FIG. 9, in one or more embodiments, for the (i+1)-th pixel driving circuit row, the first scan line G1(i+1) provides the scan signal to the second pixel driving circuit P2, and the second scan line G2(i+1) provides the scan signal to the first pixel driving circuit P1. The third metal layer 16 may also include a third auxiliary connection line 213 and a fourth auxiliary connection line 214 extending along the first direction X. The third auxiliary connection line 213 is configured to connect the first data line Data1, a second terminal of the first connection branch 141 of the first pixel driving circuit P1, and a second terminal of the first connection branch 141 of the second pixel driving circuit P2. The fourth auxiliary connection line 214 is configured to connect the second data line Data2, a second terminal of the first connection branch 141 of the third pixel driving circuit P3, and a second terminal of the first connection branch 141 of the fourth pixel driving circuit P4. In this embodiment, the first pixel driving circuit P1 and the second pixel driving circuit P2 may share one third auxiliary connection line 213 to achieve the connection to the first data line Data1, and the third pixel driving circuit P3 and the fourth pixel driving circuit P4 may share one fourth auxiliary connection line 214 to achieve the connection to the second data line Data2, thereby simplifying the arrangement of auxiliary connection lines and improving the degree of integration of the pixel driving circuit.

As shown in FIG. 9, for the i-th row of pixel driving circuit, when the first pixel driving circuit P1 and the third pixel driving circuit P3 are connected to the first scan line G1(i) and the second pixel driving circuit P2 and the fourth pixel driving circuit P4 are connected to the second scan line G2(i), it is necessary to separately provide the third auxiliary connection line 213, the fourth auxiliary connection line 214, the fifth auxiliary connection line 215, and the sixth auxiliary connection line 216 extending along the first direction X to achieve the electrical connection between the first connection branches 141 of the pixel driving circuits and the corresponding data lines. As shown in FIG. 12, when the first pixel driving circuit P1 and the fourth pixel driving circuit P4 are connected to the first scan line G1, and the second pixel driving circuit P2 and the third pixel driving circuit P3 are connected to the second scan line G2, the fourth auxiliary connection line 214 and the sixth auxiliary connection line 216 may be the same auxiliary connection line, thereby further reducing the number of auxiliary connection lines, lowering wiring complexity in the third metal layer 16, and improving the degree of integration of the pixel driving circuit.

With continued reference to FIG. 4, in one or more embodiments, the third metal layer 16 may also include a first power auxiliary line 161 extending along the first direction X and a reference auxiliary line 162 extending along the first direction X. The first power signal line PVDD is electrically connected to the first power auxiliary line 161 through a third via 164. The first power auxiliary line 161 is electrically connected to the first terminal of the second connection branch 142 through a fourth via 165. The reference voltage line SENSE is electrically connected to the reference auxiliary line 162 through a fifth via 166. The reference auxiliary line 162 is electrically connected to the second terminal of the second connection branch 142 through a sixth via 167.

In this embodiment, the first power auxiliary line 161 may extend along the first direction X throughout the entire display region of the display panel, thereby forming a grid structure with the vertical first power signal line PVDD to enhance image display uniformity of the display panel. In this embodiment, the width of the first power signal line PVDD is greater than that of the first power auxiliary line 161. The first power auxiliary line 161 has a smaller width, which can reduce the space occupied by the first power auxiliary line 161 and improve the degree of integration of the pixel driving circuit. The reference auxiliary line 162 is electrically connected to the reference voltage line SENSE corresponding to the pixel unit. The width of the reference auxiliary line 162 is less than that of the reference voltage line SENSE, thereby reducing the space occupied by the reference auxiliary line 162 and improving the degree of integration of the pixel driving circuit. Each pixel unit may be provided with one reference voltage line SENSE. Alternatively, two or more adjacent pixel units along the first direction X may share one reference voltage line SENSE, and in this case, the reference voltage line SENSE needs to cross multiple pixel units to be electrically connected to a corresponding reference voltage line SENSE. In addition, with continued reference to FIG. 4, the third metal layer 16 is also provided with a second power auxiliary line 71. The second power auxiliary line 71 may be electrically connected to the second power signal line PVEE through a via 72. Similarly, the width of the second power auxiliary line 71 is less than that of the second power signal line PVEE, thereby further improving the degree of integration of the pixel driving circuit.

With continued reference to FIG. 17 and FIG. 18, in one or more embodiments, the display panel may also include a fifth metal layer 18. The fifth metal layer 18 is disposed between the second metal layer 13 and the semiconductor layer 14. The fifth metal layer 18 is provided with an auxiliary gate 181 of the drive transistor T3. In the direction perpendicular to the substrate 11, the projection of the auxiliary gate 181 at least partially overlaps with the active layer 140 of the drive transistor T3 of the pixel driving circuit, and the projection of the auxiliary gate 181 at least partially overlaps with the gate 151 of the drive transistor T3 of the pixel driving circuit. The auxiliary gate 181 and the gate 151 of the drive transistor T3 are disposed on opposite sides of the active layer 140 of the drive transistor T3, respectively. The auxiliary gate 181 of the drive transistor T3 is electrically connected to the second electrode of the drive transistor T3. The gate 151 of the drive transistor T3 is connected to the first plate 121 of the capacitor C1. The drive transistor T3 with a dual-gate structure has stronger stability, which increases the peak percentage of threshold statistic (PPTS) of the display panel, improves the control accuracy of the drive current of the pixel driving circuit, and enhances the display effect of the display panel. In one or more embodiments, to further improve the stability of the drive transistor T3, the size of the auxiliary gate 181 of the drive transistor T3 may be greater than the size of the gate 151 of the drive transistor T3.

With continued reference to FIG. 4 and FIG. 17, in one or more embodiments, the third metal layer 16 may also include a crossover portion 163. The crossover portion 163 is electrically connected to the auxiliary gate 181 through a seventh via 168. The crossover portion 163 is electrically connected to the second node N2 of the second connection branch 142 through an eighth via 169. The crossover portion 163 is electrically connected to the first terminal of the first connection branch 141 through a ninth via 170. The crossover portion 163 is used to connect the auxiliary gate 181 to the second node N2 (that is, the second electrode of the drive transistor T3) and to connect the second electrode of the first transistor T1 (that is, the first node N1). Multiple connection functions are achieved through a crossover portion 163, which simplifies the wiring arrangement, reduces wiring complexity in the third metal layer 16, and improves the degree of integration of the pixel driving circuit.

In one or more embodiments, the third metal layer 16 may also be provided with a seventh auxiliary connection line 217. The second plate 131 of the storage capacitor C1 is provided with an avoidance via CN5. The seventh auxiliary connection line 217 connects the first plate 121 of the storage capacitor C1 and the gate 151 of the drive transistor T3 of the pixel driving circuit through the avoidance via CN5. When it is necessary to connect the first plate 121 of the storage capacitor C1 and the gate 151 of the drive transistor T3 of the pixel driving circuit, the avoidance via CN5 is disposed in the second plate 131 to avoid the need for an additional crossover line to achieve the connection. This embodiment helps improve the degree of integration of the pixel driving circuit, reduce the planar occupied area of the pixel driving circuit, and facilitate the achievement of a display panel with high resolution.

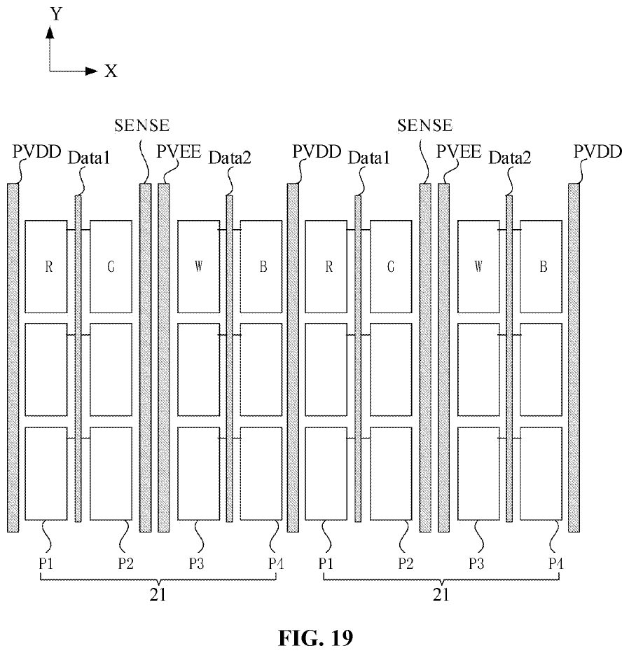

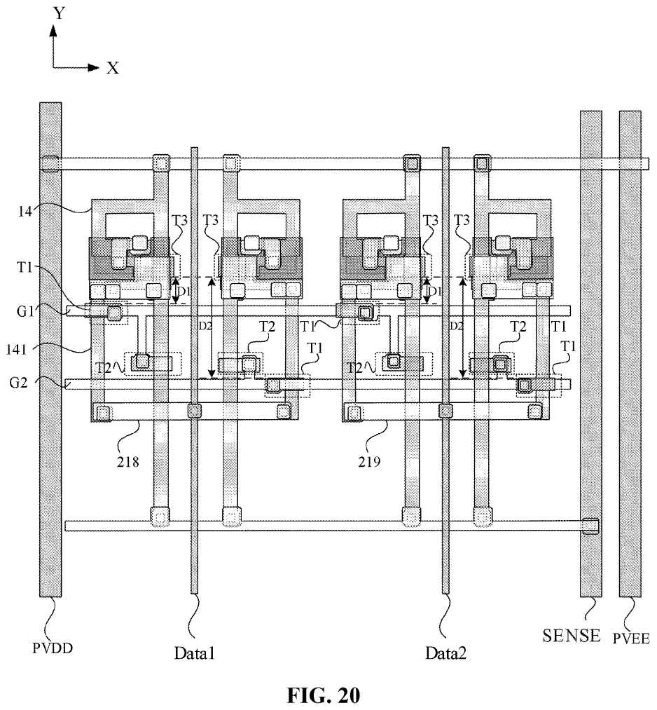

FIG. 19 is a diagram illustrating a partial structure of another display panel according to an embodiment of the present disclosure. FIG. 20 is a diagram illustrating a layout of another pixel driving circuit according to an embodiment of the present disclosure. With reference to FIG. 19 and FIG. 20, in one or more embodiments, along the first direction X, the first data line Data1 may be disposed between the first pixel driving circuit P1 and the second pixel driving circuit P2, and the second data line Data2 may be disposed between the third pixel driving circuit P3 and the fourth pixel driving circuit P4. The display panel may also include an eighth auxiliary connection line 218 and a ninth auxiliary connection line 219 extending along the first direction X. The eighth auxiliary connection line 218 connects the first data line Data 1 to a first electrode of the first transistor T1 of the first pixel driving circuit P1 and a first electrode of the first transistor T1 of the second pixel driving circuit P2. The ninth auxiliary connection line 219 connects the second data line Data2 to the first electrode of a first transistor T1 of the third pixel driving circuit P3 and a first electrode of the first transistor T1 of the fourth pixel driving circuit P4.

In the preceding embodiments, the first data line Data1 is disposed on a side of the first pixel driving circuit P1 facing away from the second pixel driving circuit P2, and the second data line Data2 is disposed on a side of the third pixel driving circuit P3 facing away from the fourth pixel driving circuit P4. In this embodiment, the first data line Data1 is disposed between the first pixel driving circuit P1 and the second pixel driving circuit P2, and the second data line Data2 is disposed between the third pixel driving circuit P3 and the fourth pixel driving circuit P4. The third metal layer 16 may also include an eighth auxiliary connection line 218 and a ninth auxiliary connection line 219 extending along the first direction X. The first electrode of the first transistor T1 of the first pixel driving circuit P1 and the first electrode of the first transistor T1 of the second pixel driving circuit P2 are both connected to the first data line Data1 through the eighth auxiliary connection line 218. The first electrode of the first transistor T1 of the third pixel driving circuit P3 and the first electrode of the first transistor T1 of the fourth pixel driving circuit P4 are connected to the second data line Data 2 through the ninth auxiliary connection line 219. In this case, the first connection branches 141 of the first pixel driving circuit P1, the second pixel driving circuit P2, the third pixel driving circuit P3, and the fourth pixel driving circuit P4 all intersect with the first scan line G1 and the second scan line G2. In this embodiment, the first pixel driving circuit P1 and the second pixel driving circuit P2 share the eighth auxiliary connection line 218, and the third pixel driving circuit P3 and the fourth pixel driving circuit P4 share the ninth auxiliary connection line 219. This embodiment helps simplify the layout of the pixel driving circuits, improves the degree of integration of the pixel driving circuits, and saves manufacturing costs of the display panel.

With continued reference to FIG. 19 and FIG. 20, in one or more embodiments, the display panel may include a semiconductor layer 14. The semiconductor layer 14 of each pixel driving circuit includes a first connection branch 141 and a second connection branch 142 extending along the second direction Y. In a direction perpendicular to the substrate 11, the overlapping region between the first connection branch 141 and the gate of the first transistor T1 is the channel S1 of the first transistor T1. In the direction perpendicular to the substrate 11, the overlapping region between the second connection branch 142 and the gate of the drive transistor T3 is the channel S3 of the drive transistor T3, and the overlapping region between the second connection branch 142 and the gate of the second transistor T2 is the channel S2 of the second transistor T2. In the direction perpendicular to the substrate 11, the first connection branch 141 of the first pixel driving circuit P1 intersects with both the first scan line G1 and the second scan line G2. In the direction perpendicular to the substrate 11, the first connection branch 141 of the second pixel driving circuit P2 intersects with both the second scan line G2 and the first scan line G1.

In this embodiment, the semiconductor layer 14 includes a first connection branch 141 and a second connection branch 142 extending along the second direction Y. The first connection branch 141 and the second connection branch 142 are disconnected. When the data line is disposed between two pixel driving circuits connected to the data line, the eighth auxiliary connection line 218 and the ninth auxiliary connection line 219 are disposed on a side of the second scan line G2 facing away from the first scan line G1. Therefore, the eighth auxiliary connection line 218 and the ninth auxiliary connection line 219 may be directly electrically connected to the second terminals of the first connection branches 141 without the need to provide additional crossover lines. This configuration simplifies the wiring arrangement of the pixel circuits and improves the degree of integration of the pixel driving circuits. The overlapping region between the first connection branch 141 and the gate of the first transistor T1 is the channel S1 of the first transistor T1. The overlapping region between the second connection branch 142 and the gate of the drive transistor T3 is the channel S3 of the drive transistor T3. The overlapping region between the second connection branch 142 and the gate of the second transistor T2 is the channel S2 of the second transistor T2. However, since the eighth auxiliary connection line 218 and the ninth auxiliary connection line 219 are disposed on a side of the second scan line G 2 away from the first scan line G1, the first connection branch 141 of each pixel driving circuit intersects with both the second scan line G2 and the first scan line G1. In this embodiment, the second connection branch 142 also serves as the connection line between the second transistor T2 and the drive transistor T3, as the connection line between the drive transistor T3 and the first power signal, and as the connection line between the second transistor T2 and the reference voltage. In this embodiment, the entire circuit path for the first power signal, the drive transistor T3, the second transistor T2, and the reference voltage is achieved by means of the second connection branch 142 that runs through the pixel driving circuit. No additional crossover lines are required to perform the above connection functions. The wiring structure is simple, which reduces wiring complexity and manufacturing costs of the display panel.

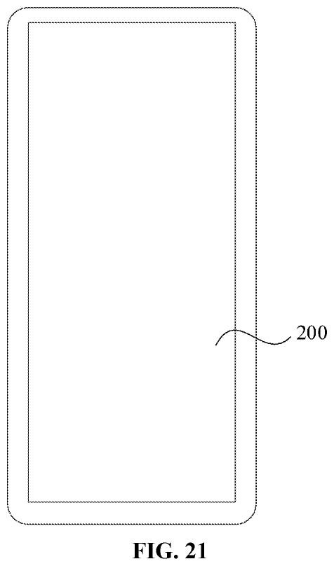

Embodiments of the present disclosure also provide a display device. FIG. 21 is a diagram illustrating the structure of a display device according to an embodiment of the present disclosure. As shown in FIG. 21, the display device provided by this embodiment of the present disclosure includes the display panel 200 according to any embodiment of the present disclosure. The display device may be a mobile phone 200 as shown in FIG. 21, or may be a computer, a television, a smart wearable device or the like, which is not specifically limited in the embodiment.

It is to be noted that the above are only preferred embodiments of the present disclosure and the technical principles used therein. It is to be understood by those skilled in the art that the present disclosure is not limited to the embodiments described herein. For those skilled in the art, various apparent modifications, adaptations, and substitutions may be made without departing from the scope of the present disclosure. Therefore, while the present disclosure is described in detail via the preceding embodiments, the present disclosure is not limited to the preceding embodiments and may include more equivalent embodiments without departing from the concept of the present disclosure. The scope of the present disclosure is determined by the scope of the appended claims.

What is claimed is:

1. A display panel, comprising:
a substrate;
pixel driving circuits, wherein a pixel driving circuit of the pixel driving circuits at least comprises a first transistor and a drive transistor, a gate of the first transistor is configured to receive a scan signal, and the pixel driving circuits at least comprise a first pixel driving circuit and a second pixel driving circuit arranged along a first direction;
a first data line extending along a second direction, wherein the first data line is configured to provide a data signal to the first pixel driving circuit and the second pixel driving circuit, and the first direction intersects with the second direction; and
a first scan line and a second scan line extending along the first direction, wherein the first scan line is configured to provide the scan signal to a gate of a first transistor of one of the first pixel driving circuit or the second pixel driving circuit, and the second scan line is configured to provide the scan signal to a gate of a first transistor of another of the first pixel driving circuit or the second pixel driving circuit;
wherein along the second direction, a distance from the first transistor of the first pixel driving circuit to a corresponding drive transistor of the first pixel driving circuit is D1, a distance from the first transistor of the second pixel driving circuit to a corresponding drive transistor of the second pixel driving circuit is D2, and |D1−D2|>0.

2. The display panel according to claim 1, wherein the pixel driving circuits further comprise a third pixel driving circuit and a fourth pixel driving circuit arranged along the first direction; along the first direction, the first pixel driving circuit, the second pixel driving circuit, the third pixel driving circuit and the fourth pixel driving circuit constitute a pixel unit; and the display panel further comprises:
a second data line extending along the second direction, wherein the second data line is configured to provide a data signal to the third pixel driving circuit and the fourth pixel driving circuit;
wherein along the second direction, a distance from the first transistor of the third pixel driving circuit to a corresponding drive transistor of the third pixel driving circuit is D3, a distance from the first transistor of the fourth pixel driving circuit to a corresponding drive transistor of the fourth pixel driving circuit is D 4, and |D3−D4|>0.

3. The display panel according to claim 2, wherein the first scan line is configured to provide the scan signal to a gate of a first transistor of one of the third pixel driving circuit or the fourth pixel driving circuit, and the second scan line is configured to provide the scan signal to a gate of a first transistor of another of the third pixel driving circuit or the fourth pixel driving circuit.

4. The display panel according to claim 1, wherein in a direction perpendicular to a plane where the substrate is located, a projection of the first scan line at least partially overlaps with the gate of the first transistor of the first pixel driving circuit, and a projection of the second scan line at least partially overlaps with the gate of the first transistor of the second pixel driving circuit; and
in the direction perpendicular to the plane where the substrate is located, the projection of the first scan line at least partially overlaps with the gate of the first transistor of the third pixel driving circuit, and the projection of the second scan line at least partially overlaps with the gate of the first transistor of the fourth pixel driving circuit.

5. The display panel according to claim 3, further comprising: a shift register circuit;
wherein a plurality of pixel units are arranged along the first direction to form a pixel driving circuit row, and the shift register circuit is electrically connected to the pixel driving circuit row correspondingly and configured to output the scan signal; and
in one pixel driving circuit row, the first scan line is configured to provide the scan signal to the gate of the first transistor of the first pixel driving circuit and the gate of the first transistor of the third pixel driving circuit, and the second scan line is configured to provide the scan signal to the gate of the first transistor of the second pixel driving circuit and the gate of the first transistor of the fourth pixel driving circuit.

6. The display panel according to claim 3, further comprising: a shift register circuit;
wherein a plurality of pixel units are arranged along the first direction to form pixel driving circuit rows, and the shift register circuit is electrically connected to the pixel driving circuit rows correspondingly and configured to output the scan signal;
in an i-th pixel driving circuit row, the first scan line is configured to provide the scan signal to the gate of the first transistor of the first pixel driving circuit and the gate of the first transistor of the third pixel driving circuit, and the second scan line is configured to provide the scan signal to the gate of the first transistor of the second pixel driving circuit and the gate of the first transistor of the fourth pixel driving circuit; and
in an (i+1)-th pixel driving circuit row, the first scan line is configured to provide the scan signal to the gate of the first transistor of the second pixel driving circuit and the gate of the first transistor of the fourth pixel driving circuit, and the second scan line is configured to provide the scan signal to the gate of the first transistor of the first pixel driving circuit and the gate of the first transistor of the third pixel driving circuit; wherein i is an integer, 1≤i≤M−1, and M is a total number of the pixel driving circuit rows.

7. The display panel according to claim 3, further comprising: a shift register circuit;
wherein a plurality of pixel units are arranged along the first direction to form a pixel driving circuit row, and the shift register circuit is electrically connected to the pixel driving circuit row correspondingly and configured to output the scan signal; and
in one pixel driving circuit row, the first scan line is configured to provide the scan signal to the gate of the first transistor of the first pixel driving circuit and the gate of the first transistor of the fourth pixel driving circuit, and the second scan line is configured to provide the scan signal to the gate of the first transistor of the second pixel driving circuit and the gate of the first transistor of the third pixel driving circuit.

8. The display panel according to claim 3, further comprising: a shift register circuit;
wherein a plurality of pixel units are arranged along the first direction to form pixel driving circuit rows, and the shift register circuit is electrically connected to the pixel driving circuit rows correspondingly and configured to output the scan signal;
in an i-th pixel driving circuit row, the first scan line is configured to provide the scan signal to the gate of the first transistor of the first pixel driving circuit and the gate of the first transistor of the fourth pixel driving circuit, and the second scan line is configured to provide the scan signal to the gate of the first transistor of the second pixel driving circuit and the gate of the first transistor of the third pixel driving circuit; and
in an (i+1)-th pixel driving circuit row, the first scan line is configured to provide the scan signal to the gate of the first transistor of the second pixel driving circuit and the gate of the first transistor of the third pixel driving circuit, and the second scan line is configured to provide the scan signal to the gate of the first transistor of the first pixel driving circuit and the gate of the first transistor of the fourth pixel driving circuit; wherein i is an integer, 1≤i≤M−1, and M is a total number of the pixel driving circuit rows.

9. The display panel according to claim 2, wherein the pixel driving circuit further comprises: a storage capacitor, a second transistor, and a light-emitting element;
a first electrode of the first transistor is configured to receive the data signal, a second electrode of the first transistor is electrically connected to a gate of the drive transistor, a first electrode of the drive transistor is configured to receive a first power signal, a second electrode of the drive transistor is electrically connected to a first electrode of the second transistor, a second electrode of the second transistor is configured to output a sensing signal, a first plate of the storage capacitor is electrically connected to the gate of the drive transistor, a second plate of the storage capacitor is electrically connected to the second electrode of the drive transistor, and a gate of the second transistor is electrically connected to the gate of the first transistor; and
the second electrode of the drive transistor is configured to be connected to a first terminal of the light-emitting element, and a second terminal of the light-emitting element is configured to receive a second power signal;
wherein along the second direction, the gate of the second transistor is disposed between the first scan line and the second scan line.

10. The display panel according to claim 9, wherein the first scan line is configured to provide the scan signal to the first pixel driving circuit, the second scan line is configured to provide the scan signal to the second pixel driving circuit; and
the display panel further comprises: a first auxiliary connection line and a second auxiliary connection line extending along the second direction, the first auxiliary connection line is configured to connect the gate of the second transistor of the first pixel driving circuit to the first scan line, and the second auxiliary connection line is configured to connect the gate of the second transistor of the second pixel driving circuit to the second scan line.

11. The display panel according to claim 9, further comprising: a reference voltage line extending along the second direction, wherein the reference voltage line is electrically connected to a second electrode of the second transistor; and
at least two pixel units are connected to a same reference voltage line.

12. The display panel according to claim 2, wherein along the first direction, the first data line is disposed on a side of the first pixel driving circuit facing away from the second pixel driving circuit, and the second data line is disposed on a side of the third pixel driving circuit facing away from the fourth pixel driving circuit;
the display panel further comprises: a third auxiliary connection line and a fourth auxiliary connection line extending along the first direction; and
the third auxiliary connection line connects the first data line to a first electrode of the first transistor of the second pixel driving circuit, and the fourth auxiliary connection line connects the second data line to a first electrode of the first transistor of the fourth pixel driving circuit.

13. The display panel according to claim 9, wherein the display panel comprises: a first metal layer, a second metal layer, a semiconductor layer, a gate layer, a third metal layer, and a fourth metal layer sequentially disposed on the substrate; and
the first metal layer is provided with the first plate of the storage capacitor, the second metal layer is provided with the second plate of the storage capacitor, the semiconductor layer is provided with active layers of transistors of the pixel driving circuit, the gate layer is provided with gates of the transistors of the pixel driving circuit, the third metal layer is provided with the first scan line and the second scan line, and the fourth metal layer is provided with a first power line, a second power signal line, a reference voltage line, the first data line, and the second data line.

14. The display panel according to claim 13, wherein the first scan line is configured to provide the scan signal to the first pixel driving circuit, and the second scan line is configured to provide the scan signal to the second pixel driving circuit;
in a direction perpendicular to the substrate, the first scan line is electrically connected to the gate of the first transistor of the first pixel driving circuit through a first via, and the second scan line is electrically connected to the gate of the first transistor of the second pixel driving circuit through a second via;
the third metal layer further comprises a first auxiliary connection line and a second auxiliary connection line extending along the second direction; and
the first scan line is electrically connected to the gate of the second transistor of the first pixel driving circuit through the first auxiliary connection line, and the second scan line is electrically connected to the gate of the second transistor of the second pixel driving circuit through the second auxiliary connection line.

15. The display panel according to claim 13, wherein the semiconductor layer of the pixel driving circuit comprises: a first connection branch and a second connection branch extending along the second direction;
in a direction perpendicular to the substrate, an overlapping region between the first connection branch and the gate of the first transistor is a channel of the first transistor; and
in the direction perpendicular to the substrate, an overlapping region between the second connection branch and the gate of the drive transistor is a channel of the drive transistor, an overlapping region between the second connection branch and the gate of the second transistor is a channel of the second transistor, a first terminal of the second connection branch is configured to receive the first power signal, a second terminal of the second connection branch is configured to be connected to the reference voltage line, and the second connection branch forms a second node between the channel of the drive transistor and the channel of the second transistor.

16. The display panel according to claim 15, wherein the first scan line is configured to provide the scan signal to the first pixel driving circuit, and the second scan line is configured to provide the scan signal to the second pixel driving circuit;
in the direction perpendicular to the substrate, the first connection branch of the first pixel driving circuit intersects with the first scan line; and
in the direction perpendicular to the substrate, the first connection branch of the second pixel driving circuit intersects with both the second scan line and the first scan line.

17. The display panel according to claim 16, wherein the first scan line is configured to provide the scan signal to the third pixel driving circuit, the second scan line is configured to provide the scan signal to the fourth pixel driving circuit, and the third metal layer further comprises: a third auxiliary connection line, a fourth auxiliary connection line, a fifth auxiliary connection line, and a sixth auxiliary connection line extending along the first direction;
the fifth auxiliary connection line is configured to connect the first data line to a second terminal of the first connection branch of the first pixel driving circuit, and the third auxiliary connection line is configured to connect the first data line to a second terminal of the first connection branch of the second pixel driving circuit; and
the sixth auxiliary connection line is configured to connect the second data line to a second terminal of the first connection branch of the third pixel driving circuit, and the fourth auxiliary connection line is configured to connect the second data line to a second terminal of the first connection branch of the fourth pixel driving circuit.

18. The display panel according to claim 15, wherein the first scan line is configured to provide the scan signal to the second pixel driving circuit, and the second scan line is configured to provide the scan signal to the first pixel driving circuit;
in the direction perpendicular to the substrate, the first connection branch of the first pixel driving circuit intersects with both the first scan line and the second scan line; and
in the direction perpendicular to the substrate, the first connection branch of the second pixel driving circuit intersects with both the second scan line and the first scan line.

19. The display panel according to claim 11, wherein along the first direction, the first data line is disposed between the first pixel driving circuit and the second pixel driving circuit, and the second data line is disposed between the third pixel driving circuit and the fourth pixel driving circuit;
the display panel further comprises: an eighth auxiliary connection line and a ninth auxiliary connection line extending along the first direction; and
the eighth auxiliary connection line connects the first data line to a first electrode of the first transistor of the first pixel driving circuit and to a first electrode of the first transistor of the second pixel driving circuit, and the ninth auxiliary connection line connects the second data line to a first electrode of the first transistor of the third pixel driving circuit and to a first electrode of the first transistor of the fourth pixel driving circuit.

20. A display device, comprising a display panel;
wherein the display panel comprises:
a substrate;
pixel driving circuits, wherein a pixel driving circuit of the pixel driving circuits at least comprises a first transistor and a drive transistor, a gate of the first transistor is configured to receive a scan signal, and the pixel driving circuits at least comprise a first pixel driving circuit and a second pixel driving circuit arranged along a first direction;
a first data line extending along a second direction, wherein the first data line is configured to provide a data signal to the first pixel driving circuit and the second pixel driving circuit, and the first direction intersects with the second direction; and
a first scan line and a second scan line extending along the first direction, wherein the first scan line is configured to provide the scan signal to a gate of a first transistor of one of the first pixel driving circuit or the second pixel driving circuit, and the second scan line is configured to provide the scan signal to a gate of a first transistor of another of the first pixel driving circuit or the second pixel driving circuit;
wherein along the second direction, a distance from the first transistor of the first pixel driving circuit to a corresponding drive transistor of the first pixel driving circuit is D1, a distance from the first transistor of the second pixel driving circuit to a corresponding drive transistor of the second pixel driving circuit is D2, and |D1−D2|>0.
